(19) United States
(12) Patent Application Publication
(10) Pub. No.: US 2026/0333903 A1
(43) Pub. Date: Oct. 22, 2026

(54) PHOTODETECTION DEVICE

(71) Applicant: SONY SEMICONDUCTOR SOLUTIONS CORPORATION, KANAGAWA (JP)

(72) Inventor: KOMOMO KODAMA, KANAGAWA (JP)

(21) Appl. No.: 18/880,572

(22) PCT Filed: Jul. 10, 2023
(86) PCT No.: PCT/JP2023/025403

§ 371 Date: Jan. 2, 2025

(30) Foreign Application Priority Data
Jul. 25, 2022 (JP) 2022-117761

(51) Int. Cl. H10F 39/00; H04N 25/709

(52) U.S. Cl. CPC H10F 39/8037; H04N 25/709

(57) ABSTRACT

The present disclosure relates to a photodetection device capable of providing a photodetection device with improved modulation power. A photodetection device includes a photogate electrode provided above a photodiode and one or more transfer transistors that transfer charge obtained as a result of photoelectric conversion performed by the photodiode to a charge storage unit. The transfer transistors are vertical transistors each including a buried gate electrode portion in which a gate electrode is buried in a semiconductor substrate. The technology of the present disclosure can be applied to, for example, a distance measuring module that measures a distance to a subject.

### TECHNICAL FIELD

The present disclosure relates to a photodetection device, and particularly to a photodetection device capable of improving modulation power.

### BACKGROUND ART

Distance sensors that measure a distance to an object by a time of flight (ToF) method are known. The distance sensors based on the ToF method performs, using a photodiode, photoelectric conversion on reflected light, which is light emitted from a light source and reflected from an object. Signal charge generated as a result of the photoelectric conversion is distributed to two charge storage units by a pair of gate electrodes driven alternately.

Patent Document 1, for example, discloses a distance sensor that includes a photogate electrode, first and second gate electrodes, and first and second semiconductor regions, that applies charge transfer signals having different phases to the first gate electrode and the second gate electrode, and that distributes charge generated in a semiconductor substrate due to incidence of pulsed light to regions immediately below the first and second gate electrodes.

### CITATION LIST

### Patent Document

Patent Document 1: Japanese Patent Application Laid-Open No. 2011-112614

### SUMMARY OF THE INVENTION

### Problems to be Solved by the Invention

In the distance sensor of Patent Document 1, planar MOS transistors are employed as the photogate electrode and the gate electrodes. In the case of planar MOS transistors, there is a concern that modulation power is small and a distribution electric field is hardly applied. In order to enhance the distribution electric field, it is desired to enhance the modulation power.

The present disclosure has been made in view of such circumstances, and aims to improve modulation power.

### Solutions to Problems

A photodetection device according to a first aspect of the present disclosure is a photodetection device including a photogate electrode provided above a photodiode and one or more transfer transistors that transfer charge obtained as a result of photoelectric conversion performed by the photodiode to a charge storage unit. The transfer transistors are vertical transistors each including a buried gate electrode portion in which a gate electrode is buried in a semiconductor substrate.

In the first aspect of the present disclosure, a photogate electrode provided above a photodiode and one or more transfer transistors that transfer charge obtained as a result of photoelectric conversion performed by the photodiode to a charge storage unit are provided. The transfer transistors are vertical transistors each including a buried gate electrode portion in which a gate electrode is buried in a semiconductor substrate.

A photodetection device according to a second aspect of the present disclosure is a photodetection device including a photogate electrode provided above a photodiode and one or more transfer transistors that transfer charge obtained as a result of photoelectric conversion performed by the photodiode to a charge storage unit. The photogate electrode is a vertical gate electrode including a buried gate electrode portion buried in a semiconductor substrate.

In the second aspect of the present disclosure, a photogate electrode provided above a photodiode and one or more transfer transistors that transfer charge obtained as a result of photoelectric conversion performed by the photodiode to a charge storage unit are provided. The photogate electrode is a vertical gate electrode including a buried gate electrode portion buried in a semiconductor substrate.

The photodetection device may be an independent device or a module incorporated into another device.

### BRIEF DESCRIPTION OF DRAWINGS

FIG. 1 is a block diagram illustrating a schematic configuration example of a photodetection device to which the present technology is applied.

FIG. 2 is a diagram illustrating a first configuration example of a photogate electrode and transfer transistors.

FIG. 3 is a diagram illustrating a second configuration example of the photogate electrode and the transfer transistors.

FIG. 4 is a diagram illustrating a third configuration example of the photogate electrode and the transfer transistors.

FIG. 5 is a diagram illustrating a difference in effect due to a relationship between width of the photogate electrode and width of the transfer transistors.

FIG. 6 is another diagram illustrating the difference in effect due to the relationship between the width of the photogate electrode and the width of the transfer transistors.

FIG. 7 is a diagram illustrating a fourth configuration example of the photogate electrode and the transfer transistors.

FIG. 8 is a diagram illustrating a fifth configuration example of the photogate electrode and the transfer transistors.

FIG. 9 is a diagram illustrating an effect in a case where the photogate electrode is a vertical gate electrode.

FIG. 10 is another diagram illustrating the effect in the case where the photogate electrode is a vertical gate electrode.

FIG. 11 is a diagram illustrating driving of the photogate electrode and the transfer transistors.

FIG. 12 is another diagram illustrating the driving of the photogate electrode and the transfer transistors.

FIG. 13 is a diagram illustrating a first circuit configuration example of a pixel.

FIG. 14 is a diagram illustrating a second circuit configuration example of the pixel.

FIG. 15 is a diagram illustrating a first arrangement example in a case where a charge storage unit is a memory MEM.

FIG. 16 is a diagram illustrating a second arrangement example in the case where the charge storage unit is a memory MEM.

FIG. 17 is a diagram illustrating an example in which one transfer transistor is arranged in one pixel.

FIG. 18 is a diagram illustrating an example in which four transfer transistors are arranged in one pixel.

FIG. 19 is a diagram for explaining an example in which the transfer transistors each include one buried gate electrode portion.

FIG. 20 is a plan view illustrating an arrangement example of a charge discharge transistor.

FIG. 21 is a plan view illustrating an arrangement example of charge discharge transistors.

FIG. 22 is a plan view illustrating an arrangement example of individual pixel transistor.

FIG. 23 is a plan view illustrating an arrangement example of the individual pixel transistors in a case where the pixel transistors are shared.

FIG. 24 is a block diagram illustrating a configuration example of a smartphone that is an electronic device to which the present technology is applied.

FIG. 25 is a block diagram illustrating an example of a schematic configuration of a vehicle control system.

FIG. 26 is an explanatory diagram illustrating an example of installation positions of an outside-vehicle information detecting unit and imaging sections.

### MODE FOR CARRYING OUT THE INVENTION

A mode for carrying out the technology of the present disclosure (hereinafter referred to as an embodiment) will be described hereinafter with reference to the accompanying drawings. The description will be made in the following order.
1. Configuration Example of Photodetection Device
2. First Configuration Example of Photogate Electrode and Transfer Transistors
3. Second Configuration Example of Photogate Electrode and Transfer Transistors
4. Third Configuration Example of Photogate Electrode and Transfer Transistors
5. Effect of Difference in Width of Photogate Electrode in Vertical Direction
6. Fourth Configuration Example of Photogate Electrode and Transfer Transistors
7. Fifth Configuration Example of Photogate Electrode and Transfer Transistors
8. Effect in Case Where Photogate Electrode Is Vertical Gate Electrode
9. Driving of Photogate Electrode and Transfer Transistors
10. Circuit Configuration Example of Pixel
11. First Arrangement Example in Case Where Charge Storage Units Are Memories
12. Second Arrangement Example in Case Where Charge Storage Units Are Memories
13. Number of Transfer Transistors
14. Number of Buried Gate Electrode Portions
15. Arrangement Example of Charge Discharge Transistor
16. Arrangement Examples of Other Pixel Transistors
17. Application Examples of Photodetection Device
18. Configuration Example of Electronic Device
19. Application Example to Mobile Body

In the drawings referred to in the following description, the same or similar parts are denoted by the same or similar reference signs, and redundant description thereof is omitted as appropriate. The drawings are schematic, and relationships between thickness and plane dimensions, a ratio of thicknesses of individual layers, and the like are different from actual ones. Furthermore, portions where a relationship or a ratio of dimensions is different between the drawings might also be included.

Furthermore, definitions of directions such as upward and downward in the following description are merely definitions for convenience of description, and do not limit the technical idea of the present disclosure. For example, in a case where an object is observed while rotating the object by 90°, upward and downward are read as being converted into left and right, and in a case where the object is observed while rotating the object by 180°, upward and downward are read as being inverted.

### 1. Configuration Example of Photodetection Device

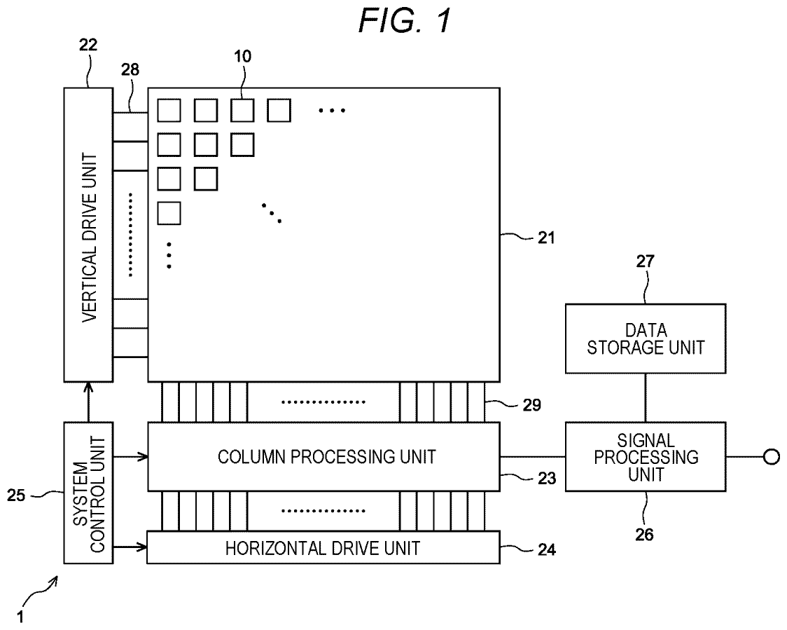

FIG. 1 is a block diagram illustrating a schematic configuration example of a photodetection device to which the present technology is applied.

A photodetection device 1 illustrated in FIG. 1 is a distance sensor that outputs distance measurement information by an indirect ToF method.

The photodetection device 1 receives light emitted from a predetermined light source (radiation light) and reflected by an object (reflected light), and outputs a depth image storing distance information to the object as a depth value. Note that the radiation light emitted from the light source is, for example, infrared light having a wavelength in a range of 780 nm to 1000 nm, and is pulsed light that is repeatedly turned on and off at a predetermined cycle.

The photodetection device 1 includes a pixel array unit 21 formed on a semiconductor substrate (not illustrated) and a peripheral circuit unit integrated on the same semiconductor substrate as the pixel array unit 21. The peripheral circuit unit includes, for example, a vertical drive unit 22, a column processing unit 23, a horizontal drive unit 24, a system control unit 25, and the like.

The photodetection device 1 is further provided with a signal processing unit 26 and a data storage unit 27. Note that the signal processing unit 26 and the data storage unit 27 may be mounted on the same substrate as the photodetection device 1, or may be arranged on a substrate in a module different from the photodetection device 1.

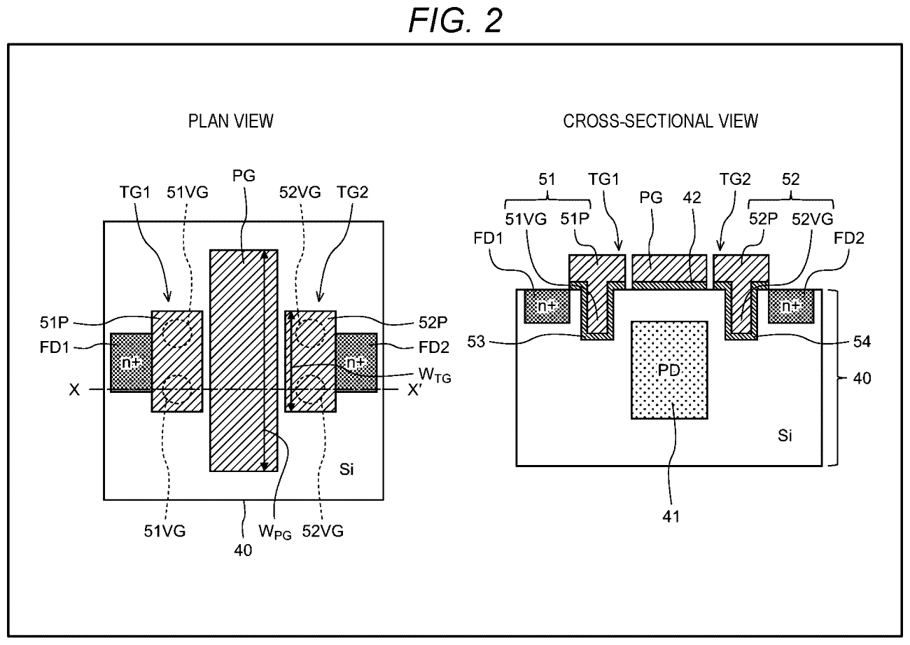

The pixel array unit 21 has a configuration in which pixels 10 that generate charge according to the amount of light received and that output signals according to the charge are arranged in two dimensions in a matrix in a row direction and a column direction. That is, the pixel array unit 21 includes a plurality of pixels 10 that performs photoelectric conversion on incident light and that outputs signals according to charge obtained as a result of the photoelectric conversion. Here, the row direction refers to an arrangement direction of the pixels 10 in a horizontal direction, and the column direction refers to an arrangement direction of the pixels 10 in a vertical direction. The row direction is a left-and-right direction in the drawing, and the column direction is an up-and-down direction in the drawing. Details of the pixels 10 will be described later with reference to FIG. 2 and subsequent drawings.

In the pixel array unit 21, a pixel drive line 28 is provided for the pixel array matrix in the row direction for each of pixel rows, and two vertical signal lines 29 are provided in the column direction for each of pixel columns. The pixel drive lines 28 transmit drive signals for driving the pixels 10 in order to read signals. Note that, although FIG. 1 illustrates each pixel drive line 28 as one wire, the number of wires used for each pixel drive line 28 is not limited to one. One end of each pixel drive line 28 is connected to an output end of the vertical drive unit 22 in the corresponding row.

The vertical drive unit 22 includes a shift register, an address decoder, and the like and drives all the individual pixels 10 of the pixel array unit 21 at the same time, in units of rows, or in another way. That is, the vertical drive unit 22 constitutes a drive unit that controls operation of the individual pixels 10 of the pixel array unit 21 together with the system control unit 25 that controls the vertical drive unit 22.

Detection signals output from the individual pixels 10 in the pixel rows in accordance with the drive control by the vertical drive unit 22 are input to the column processing unit 23 through corresponding vertical signal lines 29. The column processing unit 23 performs predetermined signal processing on the detection signal output from the individual pixels 10 through the corresponding vertical signal lines 29 and temporarily holds the detection signals subjected to the signal processing. More specifically, the column processing unit 23 performs noise removal processing, analog to digital (AD) conversion processing, and the like as the signal processing.

The horizontal drive unit 24 includes a shift register, an address decoder, and the like, and sequentially selects unit circuits in the column processing unit 23 corresponding to the pixel columns. As a result of selective scanning performed by the horizontal drive unit 24, the detection signals subjected to the signal processing performed by the column processing unit 23 in units of unit circuits are sequentially output to the signal processing unit 26.

The system control unit 25 includes a timing generator or the like that generates various timing signals, and controls driving of the vertical drive unit 22, the column processing unit 23, the horizontal drive unit 24, and the like on the basis of the various timing signals generated by the timing generator.

The signal processing unit 26 has at least an arithmetic processing function, and performs various types of signal processing such as arithmetic processing on the basis of the detection signals output from the column processing unit 23. For example, the signal processing unit 26 performs processing for generating a depth image storing distance information to an object as a depth value on the basis of the detection signals output from the column processing unit 23. The data storage unit 27 temporarily stores data necessary for the signal processing performed by the signal processing unit 26.

The photodetection device 1 configured as described above performs processing for generating a depth image storing distance information to an object as a depth value. Alternatively, the photodetection device 1 outputs, in units of pixels, detection signals that are sources of distance information to an object.

Each pixel 10 in the pixel array unit 21 includes two charge storage units, and alternately distributes charge obtained by performing photoelectric conversion on reflected light, which is radiation light reflected from an object, to the two charge storage units at regular intervals to cause the charge storage units to store the charge. Since the reflected light received by each pixel 10 is delayed from a timing at which the light source has emitted the light in accordance with a distance to the object, a distribution ratio of charge stored in the two charge storage units changes in accordance with delay time according to the distance to the object. The distance to the object can be obtained from the distribution ratio of charge stored in the two charge storage units.

Configuration of a distribution unit that distributes charge generated by a photoelectric conversion element to the two charge storage units in the structure of each pixel 10 included in the pixel array unit 21 will be described hereinafter.

### 2. First Configuration Example of Photogate Electrode and Transfer Transistors

FIG. 2 is a plan view and a cross-sectional view illustrating a first configuration example of the photogate electrode and the transfer transistors. The cross-sectional view on a right side corresponds to a cross-sectional view taken along line X-X′ in the plan view on a left side.

In the first configuration example illustrated in FIG. 2, the pixel 10 includes a photodiode (PD) 41 as a photoelectric conversion element, a photogate electrode PG, transfer transistors TG1 and TG2 that are two transfer transistors TG, and floating diffusion regions FD1 and FD2 that are two floating diffusion regions FD. The two transfer transistors TG1 and TG2 correspond to a distribution unit that distributes charge, and the two floating diffusion regions FD1 and FD2 correspond to a charge storage unit that stores charge.

As illustrated in the cross-sectional view, the photodiode 41 is formed, for each pixel, in a semiconductor substrate 40 that is a silicon substrate using, for example, silicon (Si) as a semiconductor. The photodiode 41 is a pn junction photodiode in which an n-type (second conductivity type) semiconductor region is formed in an area of a p-type (first conductivity type) semiconductor region of the semiconductor substrate 40.

The photogate electrode PG is formed on a gate insulating film 42 formed on an upper surface of the substrate of the photodiode 41. The photogate electrode PG contains, for example, polysilicon, but another material (for example, a metal material) may be used, instead. The photogate electrode PG is a charge collection electrode that collects charge generated by the photodiode 41 in a region below the photogate electrode PG.

A gate electrode 51 of the transfer transistor TG1 is formed on a left side of the photogate electrode PG, and a gate electrode 52 of the transfer transistor TG2 is formed on a right side of the photogate electrode PG. In other words, the gate electrode 51 of the transfer transistor TG1 and the gate electrode 52 of the transfer transistor TG2 are arranged in such a way as to face each other across the photogate electrode PG.

The gate electrode 51 of the transfer transistor TG1 disposed on the left side of the photogate electrode PG includes a planar gate electrode portion 51P on the upper surface of the semiconductor substrate 40 and buried gate electrode portions 51VG buried in the semiconductor substrate 40. A gate insulating film 53 is formed between the gate electrode 51 and the semiconductor substrate 40. The floating diffusion region FD1 including a high-concentration n-type semiconductor region (n+) is formed in the semiconductor substrate 40 opposite to a photogate electrode PG side with the gate electrode 51 of the transfer transistor TG1 as the center.

The gate electrode 52 of the transfer transistor TG2 disposed on the right side of the photogate electrode PG includes a planar gate electrode portion 52P on the upper surface of the semiconductor substrate 40 and buried gate electrode portions 52VG buried in the semiconductor substrate 40. A gate insulating film 54 is formed between the gate electrode 52 and the semiconductor substrate 40. The floating diffusion region FD2 including a high-concentration n-type semiconductor region (n+) is formed in the semiconductor substrate 40 opposite to the photogate electrode PG side with the gate electrode 52 of the transfer transistor TG2 as the center.

As illustrated in the plan view, the gate electrode 51 of the transfer transistor TG1 includes, for example, the two buried gate electrode portions 51VG formed in a cylindrical shape. Similarly, the gate electrode 52 of the transfer transistor TG2 includes, for example, the two buried gate electrode portions 52VG formed in a cylindrical shape.

In a case where an arrangement direction of the gate electrode 51 of the transfer transistor TG1, the photogate electrode PG, and the gate electrode 52 of the transfer transistor TG2 is defined as a horizontal direction (first direction) and a direction perpendicular to the arrangement direction is defined as a vertical direction (second direction), width W_{PG} of the photogate electrode PG is formed in such a way as to be larger than width W_{TG} of the gate electrode 51 of the transfer transistor TG1 and the gate electrode 52 of the transfer transistor TG2 with respect to width in the vertical direction.

The buried gate electrode portions 51VG of the transfer transistor TG1 and the buried gate electrode portions 52VG of the transfer transistor TG2 will be referred to as buried gate electrode portions VG unless these are not particularly distinguished from each other.

In the first configuration example, as described above, the transfer transistor TG1 is a vertical transistor including the buried gate electrode portions 51VG in which the gate electrode 51 is buried in the semiconductor substrate 40. Furthermore, the transfer transistor TG2 is also a vertical transistor including the buried gate electrode portions 52VG buried in the semiconductor substrate 40. Since the transfer transistors TG1 and TG2 are vertical transistors, modulation power of the transfer transistors TG can be improved, and a distribution electric field is enhanced. Furthermore, since the photogate electrode PG is used and a potential of the photodiode 41 is controlled by voltage, it is possible to suppress deterioration of distribution characteristics due to manufacturing variations. It is therefore possible to suppress deterioration of distribution characteristics due to manufacturing variations while enhancing a distribution electric field, and it is possible to improve imaging characteristics and distance measurement characteristics.

### 3. Second Configuration Example of Photogate Electrode and Transfer Transistors

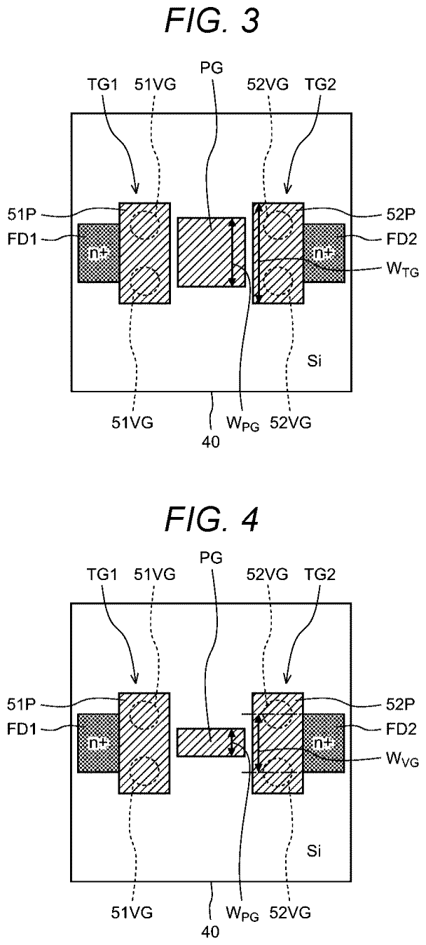

FIG. 3 is a plan view illustrating a second configuration example of the photogate electrode and the transfer transistors.

In the second configuration example of FIG. 3, parts corresponding to those of the first configuration example illustrated in FIG. 2 are given the same reference numerals, and parts different from those of the first configuration example will be described.

In the first configuration example illustrated in FIG. 2, with respect to the width in the vertical direction, the width W_{PG} of the photogate electrode PG is formed in such a way as to be larger than the width W_{TG} of the gate electrode 51 of the transfer transistor TG1 and the gate electrode 52 of the transfer transistor TG2 (width W_{PG}>width W_{TG}).

In the second configuration example of FIG. 3, on the other hand, with respect to the width in the vertical direction, the width W_{PG} of the photogate electrode PG is formed in such a way as to be equal to or smaller than the width W_{TG} of the gate electrode 51 of the transfer transistor TG1 and the gate electrode 52 of the transfer transistor TG2 (width W_{PG}=width W_{TG} or width W_{PG}<width W_{TG}). The second configuration example of FIG. 3 is formed similarly to the first configuration example illustrated in FIG. 2 except that formation size (planar region) of the photogate electrode PG is different.

### 4. Third Configuration Example of Photogate Electrode and Transfer Transistors

FIG. 4 is a plan view illustrating a third configuration example of the photogate electrode and the transfer transistors.

In the third configuration example of FIG. 4, too, parts corresponding to those of the first configuration example and the second configuration example described above are given the same reference numerals, and parts different from those of the first configuration example and the second configuration example will be described.

In the third configuration example of FIG. 4, as in the second configuration example, with respect to the width in the vertical direction, the width W_{PG} of the photogate electrode PG is formed in such a way as to be smaller than the width W_{TG} of the gate electrode 51 of the transfer transistor TG1 and the gate electrode 52 of the transfer transistor TG2 (width W_{PG}<width W_{TG}). Moreover, in the third configuration example of FIG. 4, the width W_{PG} of the photogate electrode PG is formed in such a way as to be smaller than width W_{VG} between the two buried gate electrode portions VG of the transfer transistors TG1 and TG2 (width W_{PG}>width W_{VG}). The third configuration example of FIG. 4 is formed similarly to the first configuration example illustrated in FIG. 2 except that the formation size (planar region) of the photogate electrode PG is different.

In the second configuration example and the third configuration example of the photogate electrode PG and the transfer transistors TG, the transfer transistors TG1 and TG2 are vertical transistors. As a result, the modulation power of the transfer transistors TG can be improved, and the distribution electric field is enhanced. Furthermore, since the photogate electrode PG is used and the potential of the photodiode 41 is controlled by voltage, it is possible to suppress deterioration of the distribution characteristics due to manufacturing variations. It is therefore possible to suppress deterioration of the distribution characteristics due to manufacturing variations while enhancing the distribution electric field, and it is possible to improve the imaging characteristics and the distance measurement characteristics.

### 5. Effect of Difference in Width of Photogate Electrode in Vertical Direction

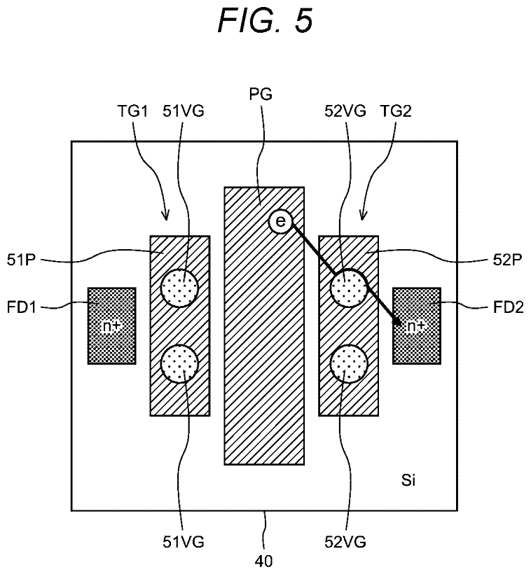

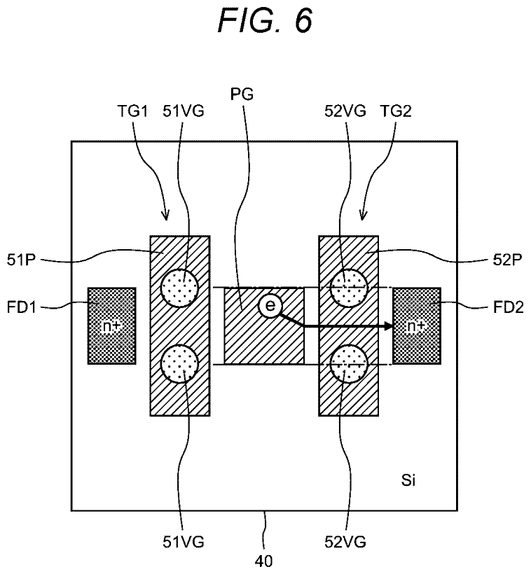

With reference to FIGS. 5 and 6, a difference in effect due to a relationship between the width W_{PG} of the photogate electrode PG in the vertical direction and the width W_{TG} of the transfer transistors TG in the vertical direction will be described. In FIGS. 5 and 6, the two buried gate electrode portions VG of the transfer transistors TG1 and TG2 are illustrated with different patterns given thereto to give priority to visibility.

In the first configuration example, charge generated by the photodiodes 41 of the semiconductor substrate 40 is randomly collected in a planar region below the photogate electrodes PG as illustrated in FIG. 5. In a case where part of the randomly collected charge collected outside the gate electrode 51 of the transfer transistor TG1 and the gate electrode 52 of the transfer transistor TG2 is collected in the floating diffusion region FD2 on the right side, for example, the charge is collected in the floating diffusion region FD2 through the outside of the two buried gate electrode portions 52VG and affected by traps at interfaces of the buried gate electrode portions 52VG. As a result, there is a concern that a charge loss or a transfer delay occurs and the imaging characteristics or the distance measurement characteristics are deteriorated.

On the other hand, as in the third configuration example, for example, in a case where the width W_{PG} of the photogate electrode PG in the vertical direction is formed in such a way as to be smaller than the width W_{VG} between the two buried gate electrode portions 52VG of the transfer transistor TG2, the charge randomly collected in the plane region below the photogate electrode PG passes between the two buried gate electrode portions 52VG and is collected in the floating diffusion region FD2 without being affected by the interfaces of the buried gate electrode portions 52VG as illustrated in FIG. 6. That is, an effect of an interface state can be suppressed, and the imaging characteristics and the distance measurement characteristics can be improved.

Among the first to third configuration examples, therefore, the second configuration example in which the width W_{PG} of the photogate electrode PG is equal to or smaller than the width W_{TG} of the transfer transistors TG is preferable as compared with the first configuration example in which the width W_{PG} is larger than the width W_{TG} of the transfer transistors TG. Moreover, the third configuration example in which the width W_{PG} of the photogate electrode PG is smaller than the width W_{VG} between the two buried gate electrode portions VG is more preferable than the second configuration example.

### 6. Fourth Configuration Example of Photogate Electrode and Transfer Transistors

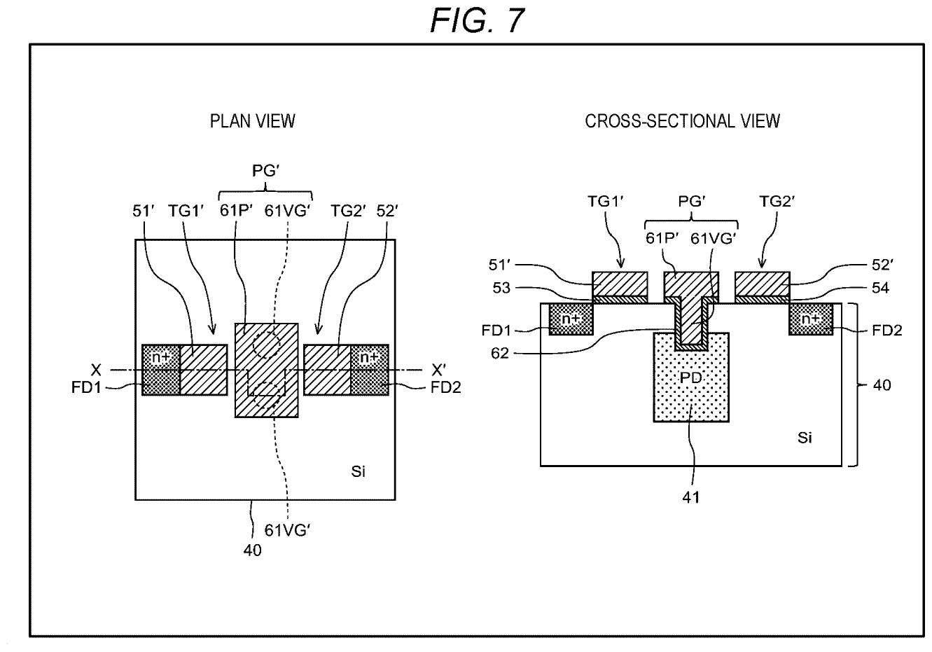

FIG. 7 is a plan view and a cross-sectional view illustrating a fourth configuration example of the photogate electrode and the transfer transistors. The cross-sectional view on a right side corresponds to a cross-sectional view taken along line X-X′ in the plan view on a left side. In the fourth configuration example of FIG. 7, parts corresponding to those of the first configuration example illustrated in FIG. 2 are given the same reference numerals, and parts different from those of the first configuration example will be described.

In the first configuration example illustrated in FIG. 2, the transfer transistors TG1 and TG2 are the vertical transistors including the two buried gate electrode portions VG, and the photogate electrode PG is a planar gate electrode.

In the fourth configuration example of FIG. 7, on the other hand, transfer transistors TG1′ and TG2′ and a photogate electrode PG′ are formed instead of the transfer transistors TG1 and TG2 and the photogate electrode PG of the first configuration example illustrated in FIG. 2.

The transfer transistor TG1′ is a planar transistor including a gate electrode portion 51′ corresponding only to the planar gate electrode portion 51P of the first configuration example. The transfer transistor TG2′, similarly, is a planar transistor including a gate electrode portion 52′ corresponding only to the planar gate electrode portion 52P of the first configuration example.

The photogate electrode PG′, on the other hand, includes a planar gate electrode portion 61P′ on the upper surface of the semiconductor substrate 40 and a buried gate electrode portion 61VG′ buried in the semiconductor substrate 40. A gate insulating film 62 is formed between the photogate electrode PG′ and the semiconductor substrate 40.

As illustrated in the plan view, the photogate electrode PG′ includes, for example, two buried gate electrode portions 61VG′ formed in a cylindrical shape. Depth of the buried gate electrode portions 61VG′ in a substrate thickness direction is a depth reaching the n-type semiconductor region of the photodiode 41.

In the fourth configuration example, as described above, the transfer transistors TG1′ and TG2′ are planar transistors. The photogate electrode PG′, on the other hand, is a vertical gate electrode including the planar gate electrode portion 61P′ and the buried gate electrode portions 61VG′. Since the photogate electrode PG′ is a vertical gate electrode, a distance from the photodiode 41 is shortened, and a voltage applied to the photogate electrode PG′ can be made lower than the voltage applied to the planar photogate electrode PG. Since control can be performed at a low voltage, power consumption can be suppressed.

### 7. Fifth Configuration Example of Photogate Electrode and Transfer Transistors

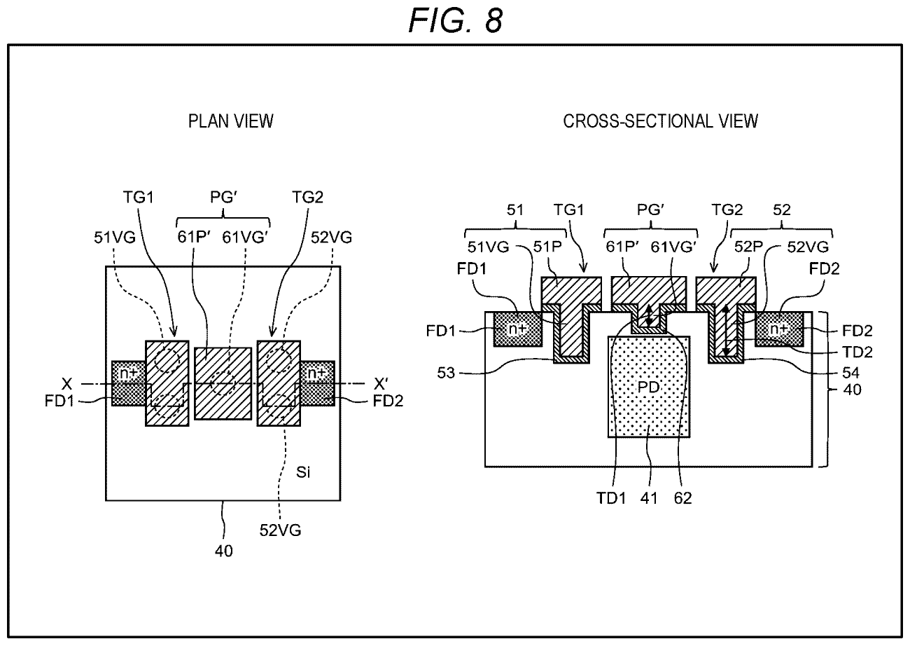

FIG. 8 is a plan view and a cross-sectional view illustrating a fifth configuration example of the photogate electrode and the transfer transistors. The cross-sectional view on a right side corresponds to a cross-sectional view taken along line X-X′ in the plan view on a left side.

In the fifth configuration example illustrated in FIG. 8, both the photogate electrode and the transfer transistors include a buried gate electrode portion.

That is, the pixel 10 in FIG. 8 includes the transfer transistors TG1 and TG2 of the first configuration example illustrated in FIG. 2 and the photogate electrode PG′ illustrated in FIG. 7. Whereas the photogate electrode PG′ illustrated in FIG. 7 includes the two buried gate electrode portions 61VG′, however, the photogate electrode PG′ of FIG. 8 includes one buried gate electrode portion 61VG′. With respect to the depth in the substrate thickness direction, the buried gate electrode portion 61VG′ is formed in such a way as to be shorter than the buried gate electrode portions VG of the transfer transistors TG1 and TG2. That is, in a case where depth of the buried gate electrode portion 61VG′ is denoted by TD1 and depth of the buried gate electrode portions VG of the transfer transistors TG1 and TG2 is denoted by TD2, TD1<TD2.

In the fifth configuration example, as described above, the transfer transistors TG1 and TG2 are vertical transistors. As a result, the modulation power of the transfer transistors TG can be improved, and the distribution electric field is enhanced. Furthermore, since the photogate electrode PG′ is used and the potential of the photodiode 41 is controlled by voltage, it is possible to suppress deterioration of the distribution characteristics due to manufacturing variations. It is therefore possible to suppress deterioration of the distribution characteristics due to manufacturing variations while enhancing the distribution electric field, and it is possible to improve the imaging characteristics and the distance measurement characteristics. Furthermore, the photogate electrode PG′ includes a vertical gate electrode. As a result, the voltage applied to the photogate electrode PG′ can be made low, and the power consumption can be suppressed.

### 8. Effect in Case Where Photogate Electrode Is Vertical Gate Electrode

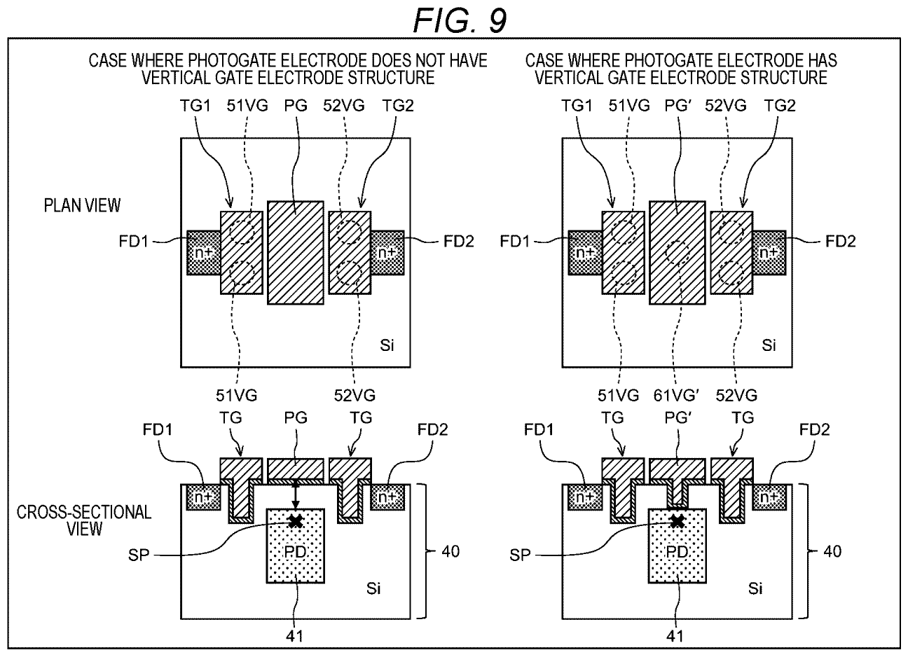

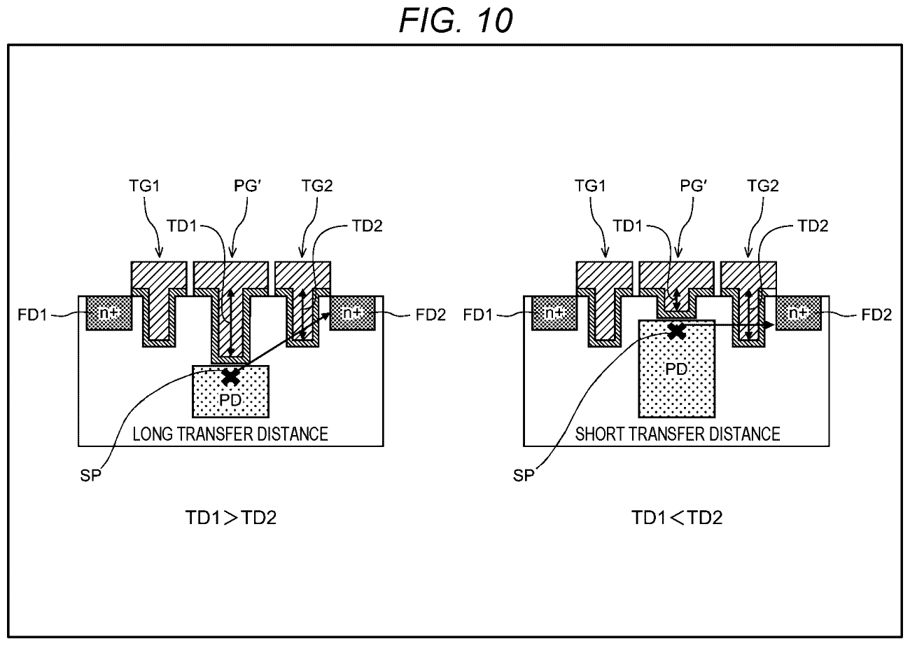

With reference to FIGS. 9 and 10, an effect in a case where the photogate electrode is a vertical gate electrode will be described.

As illustrated in a plan view and a cross-sectional view on a left side of FIG. 9, since, in the photogate electrode PG that does not have a vertical gate electrode structure, a sensor potential SP, which is a position in the photodiode 41 at which the potential is highest, and the photogate electrode PG are separated from each other in a depth direction, it is necessary to apply a high voltage to the photogate electrode PG in order to control the potential at the sensor potential SP. As a result, the power consumption increases. Furthermore, in a case where a voltage is applied to the photogate electrode PG, the sensor potential SP shifts to the vicinity of an interface of the semiconductor substrate 40 above the photodiode 41 and is easily affected by the substrate interface at a time of charge transfer.

Since the distance between the sensor potential SP and the photogate electrode PG in the depth direction becomes short in the photogate electrode PG′ having the vertical gate electrode structure, on the other hand, the applied voltage for controlling the potential at the sensor potential SP can be set to a low voltage. As a result, the power consumption can be reduced. Furthermore, by controlling the depth of the buried gate electrode portion 61VG′ of the photogate electrode PG′, the sensor potential SP can be set at a desired position in the substrate depth direction. As a result, it is possible to reduce the effect of the substrate interface at the time of charge transfer.

Furthermore, as illustrated in a cross-sectional view on a left side of FIG. 10, in a case where the depth TD1 of the buried gate electrode portion 61VG′ of the photogate electrode PG′ in the substrate thickness direction is formed in such a way as to be larger than the depth TD2 of the buried gate electrode portions VG of the transfer transistors TG1 and TG2 in the substrate thickness direction (TD1>TD2), a distance from the sensor potential SP to the floating diffusion region FD (FD1 or FD2) of a transfer destination becomes long, and it is necessary to apply a high voltage to the transfer transistors TG at the time of transfer.

As illustrated in a cross-sectional view on a right side of FIG. 10, by making the depth TD1 of the buried gate electrode portion 61VG′ of the photogate electrode PG′ in the substrate thickness direction smaller than the depth TD2 of the buried gate electrode portions VG of the transfer transistors TG1 and TG2 in the substrate thickness direction (TD1<TD2), the transfer distance can be shortened, and the voltage applied to the transfer transistors TG at the time of transfer can be made low. Furthermore, it is possible to make it difficult to be affected by distribution variation.

### 9. Driving of Photogate Electrode and Transfer Transistors

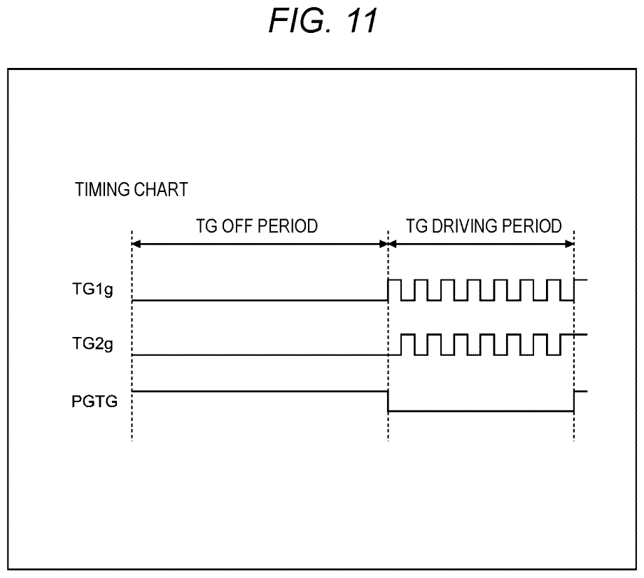

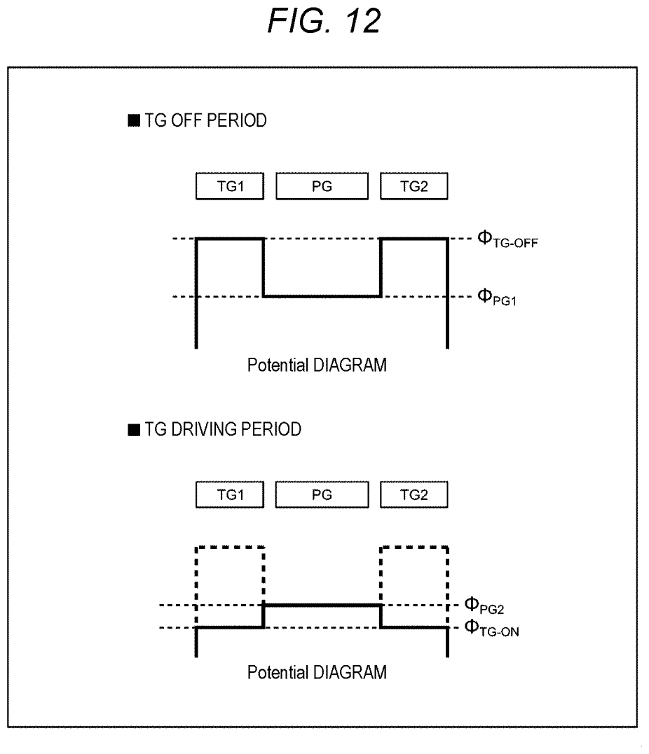

Driving of the photogate electrode and the transfer transistor will be described with reference to FIGS. 11 and 12. In FIGS. 11 and 12, the driving of the photogate electrode PG and the transfer transistors TG in the first configuration example of FIG. 2 will be described, but the same applies to the cases of the photogate electrode PG′ and the transfer transistors TG′ other than the first configuration example.

FIG. 11 is a timing chart of signals applied to the photogate electrode PG and the two transfer transistors TG1 and TG2 of the first configuration example.

A transfer drive signal TG1g is a pulse signal supplied to the gate electrode 51 of the transfer transistor TG1, and a transfer drive signal TG2g is a pulse signal supplied to the gate electrode 52 of the transfer transistor TG2. A control signal PGTG is a pulse signal supplied to the photogate electrode PG.

In order to output a detection signal (pixel signal) once, the pixel 10 has, as illustrated in FIG. 11, a TG off period in which the driving of the transfer transistor TG is turned off and a TG driving period in which driving for alternately turning on the two transfer transistors TG1 and TG2 is performed.

In the TG off period, the transfer drive signal TG1g and the transfer drive signal TG2g are set to a low level. The control signal PGTG supplied to the photogate electrode PG, on the other hand, is set to a high level in the TG off period.

In the TG driving period, on the other hand, the transfer drive signal TG1g and the transfer drive signal TG2g are alternately set to the high level, and the control signal PGTG supplied to the photogate electrode PG is set to the low level.

FIG. 12 is potential diagrams of the photogate electrode PG and the two transfer transistors TG1 and TG2 in the TG off period and the TG driving period, respectively.

In the TG off period, a first voltage Φ_{PG1} is supplied to the photogate electrode PG by the control signal PGTG, and an off voltage Φ_{TG-OFF} for turning off the transfer transistors TG is supplied to the two transfer transistors TG1 and TG2 by the transfer drive signals TG1g and TG2g. Here, a relationship between the first voltage Φ_{PG1} and the off voltage Φ_{TG-OFF} is Φ_{TG-OFF}<Φ_{PG1}, that is, the first voltage Φ_{PG1} is a voltage higher than the off voltage Φ_{TG-OFF} of the transfer transistors TG, and a potential of a semiconductor region (silicon region) under the photogate electrode PG of the semiconductor substrate 40 is set to be larger than potentials of semiconductor regions (silicon regions) under the transfer transistors TG. In other words, the potential under the photo-gate electrode PG is set to be deeper than the potentials under the transfer transistors TG. As a potential difference ΔV between the first voltage Φ_{PG1} and the off voltage Φ_{TG-OFF} increases, leakage to the floating diffusion regions FD in a case where the transfer transistors TG are off can be reduced, and parasitic light sensitivity (PLS) can be suppressed. As a result, the imaging characteristics and the distance measurement characteristics can be improved.

In the TG driving period, on the other hand, a second voltage Φ_{PG2} (Φ_{PG2}<Φ_{PG1}) is supplied to the photogate electrode PG by the control signal PGTG, and an on voltage Φ_{TG-ON} for turning on the transfer transistors TG is alternately supplied to the two transfer transistors TG1 and TG2 by the transfer drive signals TG1g and TG2g. The other of the transfer transistors TG1 and TG2 to which the on voltage Φ_{TG-ON} is not being supplied is supplied with the off voltage Φ_{TG-OFF}. Here, a relationship between the second voltage Φ_{PG2} and the on voltage Φ_{TG-ON} is Φ_{TG-ON}≥Φ_{PG2}, that is, the second voltage Φ_{PG2} is a voltage lower than or equal to the on voltage Φ_{TG-ON} of the transfer transistors TG, and the potential of the semiconductor region (silicon region) under the photogate electrode PG of the semiconductor substrate 40 is set to be lower than or equal to the potentials of the semiconductor regions (silicon regions) under the transfer transistors TG. In other words, the potentials under the transfer transistors TG turned on are set to be deeper than the potential under the photogate electrode PG. As a result, distribution variation can be suppressed, and the distance measurement characteristics can be improved.

As described above, the vertical drive unit 22 supplies the control signal PGTG having two or more levels including the first voltage Φ_{PG1} and the second voltage Φ_{PG2} to the photogate electrode PG, and applies different voltages to the photogate electrode PG in the TG off period and the TG driving period. As a result, the imaging characteristics and the distance measurement characteristics can be improved.

### 10. Circuit Configuration Example of Pixel

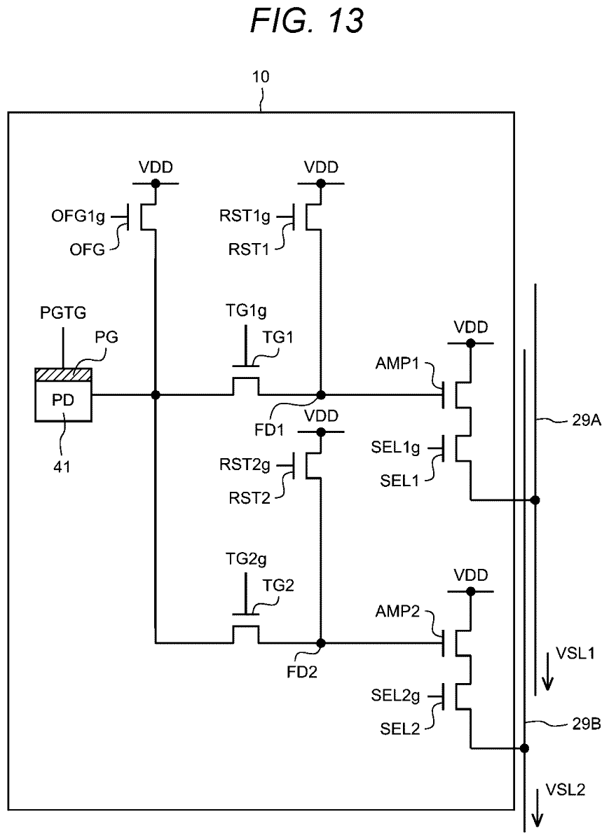

FIG. 13 illustrates a first circuit configuration example of the pixel 10 arranged in the pixel array unit 21 in two dimensions.

The first circuit configuration example illustrated in FIG. 13 is a configuration example in which the charge storage units that store distributed charge are the floating diffusion regions FD as described above.

The pixel 10 includes the photodiode (PD) 41 as a photoelectric conversion element and the photogate electrode PG formed on the upper surface of the substrate of the photodiode 41. The predetermined control signal PGTG is applied to the photogate electrode PG by the vertical drive unit 22.

Furthermore, the pixel 10 includes the two transfer transistors TG, the two floating diffusion regions FD, two amplification transistors AMP, two reset transistors RST, and two selection transistors SEL. Moreover, the pixel 10 includes a charge discharge transistor OFG.

Here, in a case where the two transfer transistors TG, the two floating diffusion region FD, the two amplification transistors AMP, the two reset transistors RST, and the two selection transistors SEL provided for the pixel 10 are distinguished from one another, these components will be referred to as the transfer transistors TG1 and TG2, the floating diffusion regions FD1 and FD2, amplification transistors AMP1 and AMP2, reset transistors RST1 and RST2, and selection transistors SEL1 and SEL2 as illustrated in FIG. 13.

The transfer transistors TG, the amplification transistors AMP, the selection transistors SEL, the reset transistors RST, and the charge discharge transistor OFG are, for example, n-type MOS transistors.

In a case where the transfer drive signal TG1g supplied to the gate electrode of the transfer transistor TG1 becomes active, the transfer transistor TG1 becomes conductive in response to this, thereby transferring the charge stored in the photodiode 41 to the floating diffusion region FD1. In a case where the transfer drive signal TG2g supplied to the gate electrode of the transfer transistor TG2 becomes active, the transfer transistor TG2 becomes conductive in response to this, thereby transferring the charge stored in the photodiode 41 to the floating diffusion region FD2.

The floating diffusion regions FD1 and FD2 are charge storage units that temporarily hold the charge transferred from the photodiode 41.

In a case where the reset drive signal RST1g supplied to a gate electrode of the reset transistor RST1 becomes active, the reset transistor RST1 becomes conductive in response to this, thereby resetting the potential of the floating diffusion region FD1. In a case where the reset drive signal RST2g supplied to a gate electrode of the reset transistor RST2 becomes active, the reset transistor RST2 becomes conductive in response to this, thereby resetting the potential of the floating diffusion region FD2.

In a case where the discharge drive signal OFG1g supplied to a gate electrode of charge discharge transistor OFG becomes active, the charge discharge transistor OFG becomes conductive in response to this, thereby discharging the charge stored in the photodiode 41.

In a case where a source electrode of the amplification transistor AMP1 is connected to a vertical signal line 29A via the selection transistor SEL1, the amplification transistor AMP1 is connected to a constant current source (not illustrated) to form a source follower circuit. In a case where a source electrode of the amplification transistor AMP2 is connected to a vertical signal line 29B via the selection transistor SEL2, the amplification transistor AMP2 is connected to the constant current source (not illustrated) to form a source follower circuit.

The selection transistor SEL1 is connected between the source electrode of the amplification transistor AMP1 and the vertical signal line 29A. In a case where a selection signal SEL1g supplied to a gate electrode of the selection transistor SEL1 becomes active, the selection transistor SEL1 becomes conductive in response to this, thereby outputting a detection signal VSL1 output from the amplification transistor AMP1 to the vertical signal line 29A.

The selection transistor SEL2 is connected between the source electrode of the amplification transistor AMP2 and the vertical signal line 29B. In a case where a selection signal SEL2g supplied to a gate electrode of the selection transistor SEL2 becomes active, the selection transistor SEL2 becomes conductive in response to this, thereby outputting a detection signal VSL2 output from the amplification transistor AMP2 to the vertical signal line 29B.

The transfer transistors TG1 and TG2, the amplification transistors AMP1 and AMP2, the selection transistors SEL1 and SEL2, and the charge discharge transistor OFG of the pixel 10 are controlled by the vertical drive unit 22.

Operation of the pixel 10 will be briefly described.

First, before reception of light starts, a reset operation for resetting charge in the pixel 10 is performed in all the pixels. That is, the charge discharge transistor OFG and the reset transistors RST1 and RST2 are turned on, and charge stored in the photodiode 41 and the floating diffusion regions FD1 and FD2 is discharged.

After the stored charge is discharged, the reception of light starts in all the pixels.

In a light receiving period, the transfer transistors TG1 and TG2 are alternately driven. That is, in a first period, the transfer transistor TG1 is turned on, and the transfer transistor TG2 is turned off. In this first period, the charge generated by the photodiode 41 is transferred to the floating diffusion region FD1. In a second period subsequent to the first period, the transfer transistor TG1 is turned off, and the transfer transistor TG2 is turned on. In this second period, the charge generated by the photodiode 41 is transferred to the floating diffusion region FD2. As a result, the charge generated by the photodiode 41 is distributed and stored in the floating diffusion regions FD1 and FD2. During a period in which the charge generated by the photodiode 41 is distributed, the control signal PGTG applied to the photogate electrode PG is set to the low level.

After the light receiving period ends, the control signal PGTG applied to the photogate electrode PG is set to the high level, and each pixel 10 of the pixel array unit 21 is selected line by line. In the selected pixel 10, the selection transistors SEL1 and SEL2 are turned on. As a result, the charge stored in the floating diffusion region FD1 is output to the column processing unit 23 via the vertical signal line 29A as the detection signal VSL1. The charge stored in the floating diffusion region FD2 is output to the column processing unit 23 via the vertical signal line 29B as the detection signal VSL2.

One light receiving operation thus ends, and a next light receiving operation starting with the reset operation is then performed.

Reflected light received by the pixel 10 is delayed in accordance with a distance to an object from a timing at which the light source emits light. Since the distribution ratio of charge stored in the two floating diffusion regions FD1 and FD2 changes depending on the delay time according to the distance to the object, the distance to the object can be obtained from the distribution ratio of charge stored in the two floating diffusion regions FD1 and FD2.

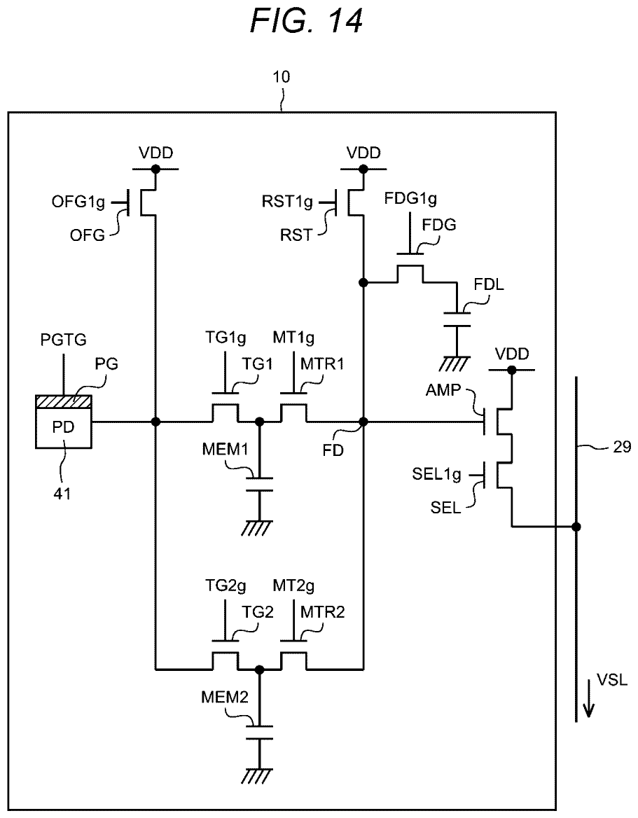

FIG. 14 illustrates a second circuit configuration example, which is another circuit configuration of the pixel 10.

Note that, in FIG. 14, parts corresponding to those in FIG. 13 are given the same reference numerals, and description thereof is omitted as appropriate.

The second circuit configuration example illustrated in FIG. 14 is a configuration example in which the charge storage units that store distributed charge are memories MEM.

A first pixel circuit illustrated in FIG. 13 includes the two transfer transistors TG, the two floating diffusion regions FD, the two amplification transistors AMP, the two reset transistors RST, and the two selection transistors SEL.

In a second pixel circuit of FIG. 14, on the other hand, the number of floating diffusions FD, reset transistors RST, amplification transistors AMP, and selection transistors SEL is changed to one. In the first pixel circuit illustrated in FIG. 13, the charge generated by the photodiode 41 is held in the floating diffusion regions FD, but in the second pixel circuit in FIG. 14, the charge is held in the memories MEM. Furthermore, in the second pixel circuit of FIG. 14, a switching transistor FDG and an additional capacitor FDL are newly provided.

The pixel 10 includes a photodiode 41, a charge discharge transistor OFG, a reset transistor RST, an amplification transistor AMP, and a selection transistor SEL. Furthermore, the pixel 10 includes two first transfer transistors TG, two second transfer transistors MTR, and two memories MEM.

Here, in a case where the two first transfer transistors TG, the two second transfer transistors MTR, and the two memories MEM are distinguished from each other in the pixel 10, these components will be referred to as first transfer transistors TG1 and TG2, second transfer transistors MTR1 and MTR2, and memories MEM1 and MEM2 as illustrated in FIG. 3.

The first transfer transistors TG, the second transfer transistors MTR, the reset transistor RST, the amplification transistor AMP, the selection transistor SEL, and the charge discharge transistor OFG are, for example, n-type MOS transistors.

In the second pixel circuit of FIG. 14, the charge generated by the photodiode 41 is transferred to and held in the memories MEM1 and MEM2 provided as charge storage units.

That is, in a case where the first transfer drive signal TG1g supplied to a gate electrode of the first transfer transistor TG1 becomes active, the first transfer transistor TG1 becomes conductive in response to this, thereby transferring the charge stored in the photodiode 41 to the memory MEM1. In a case where the first transfer drive signal TG2g supplied to a gate electrode of the first transfer transistor TG2 becomes active, the first transfer transistor TG2 becomes conductive in response to this, thereby transferring the charge stored in the photodiode 41 to the memory MEM2.

Furthermore, in a case where the second transfer drive signal MT1g supplied to a gate electrode of the second transfer transistor MTR1 becomes active, the second transfer transistor MTR1 becomes conductive in response to this, thereby transferring the charge stored in the memory MEM1 to the floating diffusion region FD. In a case where the second transfer drive signal MT2g supplied to a gate electrode of the second transfer transistor MTR2 becomes active, the second transfer transistor MTR2 becomes conductive in response to this, thereby transferring the charge stored in the memory MEM2 to the floating diffusion region FD.

In a case where the FD drive signal FDG1g supplied to a gate electrode of the switching transistor FDG becomes active, the switching transistor FDG becomes conductive, thereby connecting the additional capacitor FDL to the floating diffusion region FD.

For example, in a case of high illuminance, in which the amount of incident light is large, the vertical drive unit 22 activates the switching transistor FDG to connect the floating diffusion region FD and the additional capacitor FDL to each other. It is therefore possible to store more electric charge in the case of high illuminance.

In a case of low illuminance, in which the amount of incident light is small, the vertical drive unit 22 turns off the switching transistor FDG to separate the additional capacitor FDL from the floating diffusion region FD. As a result, conversion efficiency can be increased.

In a case where the reset drive signal RST1g supplied to a gate electrode of the reset transistor becomes active, the reset transistor RST becomes conductive in response to this, thereby resetting the potential of the floating diffusion region FD. Note that, in a case where the reset transistor RST is made active, the second transfer transistors MTR1 and MTR2 and the switching transistor FDG are also made active at the same time, and the memories MEM1 and MEM2 and the additional capacitor FDL are also reset.

A source electrode of the amplification transistor AMP is connected to the vertical signal line 29 via the selection transistor SEL, so that the amplification transistor AMP is connected to a constant current source (not illustrated) to constitute a source follower circuit. The selection transistor SEL is connected between the source electrode of the amplification transistor AMP and the vertical signal line 29. In a case where the selection signal SEL1g supplied to a gate electrode of the selection transistor SEL becomes active, the selection transistor SEL becomes conductive in response to this, thereby outputting the detection signal VSL output from the amplification transistor AMP to the vertical signal line 29.

In the second pixel circuit of FIG. 14, the charge generated by the photodiode 41 is distributed to and accumulated in the memories MEM1 and MEM2. The charge held in the memories MEM1 and MEM2 are then transferred to the floating diffusion region FD at a timing of being read, and output from the pixel 10.

Note that the circuit configuration of the pixel 10 is not limited to the configuration in FIG. 13 or 14, and other configurations may also be adopted. For example, in the configuration illustrated in FIG. 14 in which distribution charge is held in the memories MEM1 and MEM2, two amplification transistors AMP, two reset transistors RST, and two selection transistors SEL may be provided as in the first pixel circuit in FIG. 13.

Although the pixel circuit using the photogate electrode PG and the transfer transistors TG1 and TG2 illustrated in FIGS. 2 to 4 has been described for the circuit configurations of FIGS. 13 and 14, the same applies to a case where the photogate electrode PG′ and the transfer transistors TG1′ and TG2′ illustrated in FIGS. 7 and 8 are used.

### 11. First Arrangement Example in Case Where Charge Storage Units Are Memories

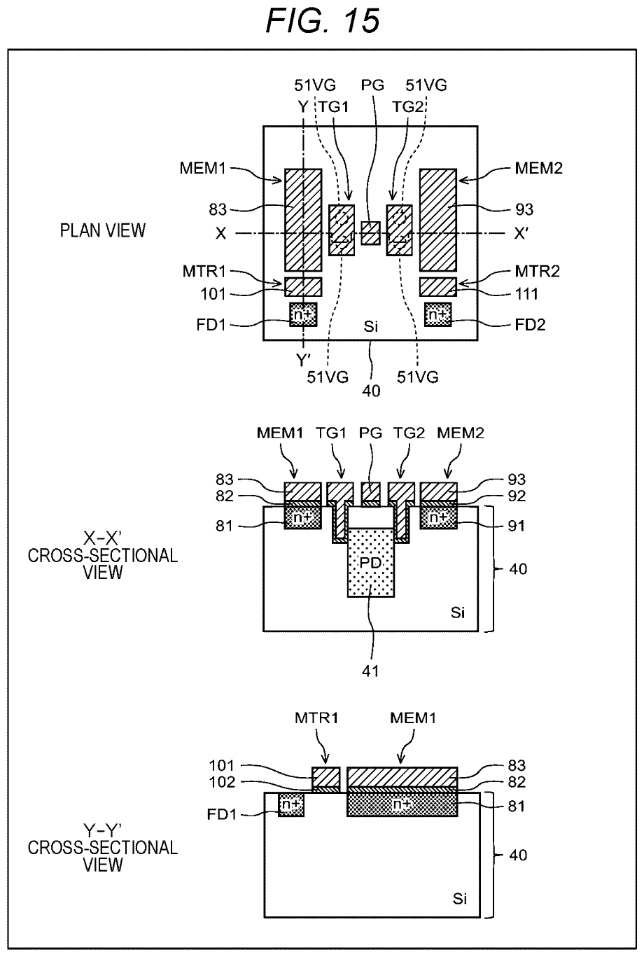

FIG. 15 is a plan view and cross-sectional views illustrating a first arrangement example of the memories MEM and the second transfer transistors MTR in a case where the charge storage units are the memories MEM as in the second pixel circuit illustrated in FIG. 14. As for the cross-sectional views, a cross-sectional view taken along line X-X′ and a cross-sectional view taken along line Y-Y′ in the plan view are illustrated.

In FIG. 15, description of the parts common to the above-described configuration and given the same reference numerals is omitted as appropriate. In FIG. 15, the first configuration example of FIG. 2 is employed for the photogate electrode PG and the transfer transistors TG, but some reference numerals are omitted for simplification.

The memory MEM1 is formed on an opposite side to the photogate electrode PG side with the first transfer transistor TG1 as the center. The memory MEM1 is configured as a MIS capacitor (MOS capacitor) including a high-concentration n-type semiconductor region (n+) 81 formed in the semiconductor substrate 40, an insulating film 82, and a gate electrode 83 containing polysilicon or the like.

Furthermore, the memory MEM2 is formed on the opposite side to the photogate electrode PG side with the first transfer transistor TG2 as the center. The memory MEM2 is configured as a MIS capacitor (MOS capacitor) including a high-concentration n-type semiconductor region (n+) 91 formed in the semiconductor substrate 40, an insulating film 92, and a gate electrode 93 containing polysilicon or the like.

In a case where an arrangement direction of the first transfer transistor TG1, the photogate electrode PG, and the first transfer transistor TG2 is defined as a horizontal direction and a direction perpendicular to the arrangement direction is defined as a vertical direction, the second transfer transistor MTR1 and the floating diffusion region FD1 are arranged side by side in the vertical direction of the memory MEM1.

The second transfer transistor MTR1 includes a gate electrode 101 containing polysilicon or the like and a gate insulating film 102, and the high-concentration n-type semiconductor region 81 of the memory MEM1 and the high-concentration n-type semiconductor region of the floating diffusion region FD1 correspond to a source region or a drain region.

Similarly, the second transfer transistor MTR2 and the floating diffusion region FD2 are arranged side by side in the vertical direction of the memory MEM2, the second transfer transistor MTR2 includes a gate electrode 111 containing polysilicon or the like and a gate insulating film (not illustrated), and the high-concentration n-type semiconductor region 91 of the memory MEM2 and the high-concentration n-type semiconductor region of the floating diffusion region FD2 correspond to a source region or a drain region. The high-concentration n-type semiconductor regions of the floating diffusion regions FD1 and FD2 are electrically connected to each other by a metal wire formed in a wiring layer, thereby constituting one floating diffusion region FD.

### 12. Second Arrangement Example in Case Where Charge Storage Units Are Memories

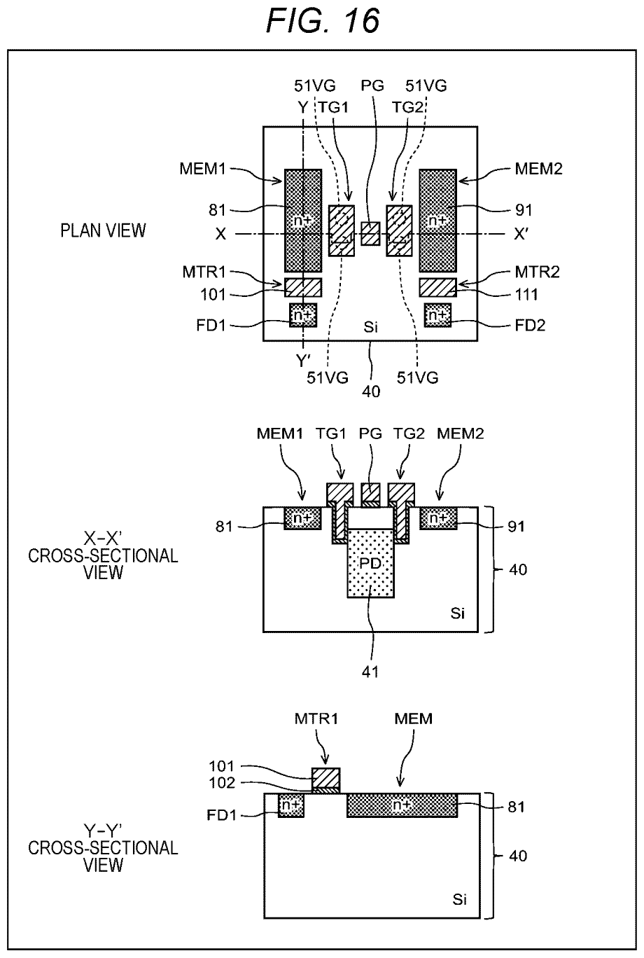

FIG. 16 is a plan view and cross-sectional views illustrating a second arrangement example of the memories MEM and the second transfer transistors MTR in a case where the charge storage units are the memories MEM as in the second pixel circuit illustrated in FIG. 14. As for the cross-sectional views, a cross-sectional view taken along line X-X′ and a cross-sectional view taken along line Y-Y′ in the plan view are illustrated.

In FIG. 16, description of parts common to the first arrangement example illustrated in FIG. 15 and given the same reference numerals is omitted as appropriate. In FIG. 16, similarly, as in FIG. 15, some reference numerals are omitted for simplification.

Although an example in which the memories MEM1 and MEM2 are configured as a MIS capacitor has been described in the first arrangement example illustrated in FIG. 15, the memories MEM1 and MEM2 may be configured with only a high-concentration n-type semiconductor region as with the floating diffusion regions FD1 and FD2.

The second arrangement example of FIG. 16 illustrates an example in which the memories MEM1 and MEM2 are configured only with a high-concentration n-type semiconductor region. In the second arrangement example of FIG. 16, as compared with the first arrangement example illustrated in FIG. 15, the insulating film 82 and the gate electrode 83 are omitted in the memory MEM1, and the insulating film 92 and the gate electrode 93 are omitted in the memory MEM2. Other components are similar to the those in the first embodiment illustrated in FIG. 15, and description thereof is omitted.

### 13. Number of Transfer Transistors

Although a configuration in which two transfer transistors TG are provided for one pixel has been described in the above-described example, the number of transfer transistors TG provided in one pixel is not limited to two.

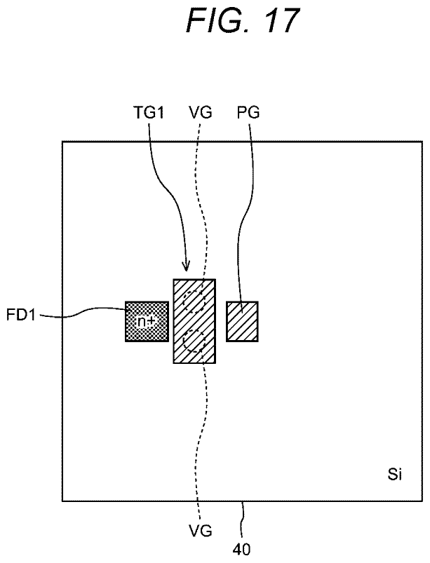

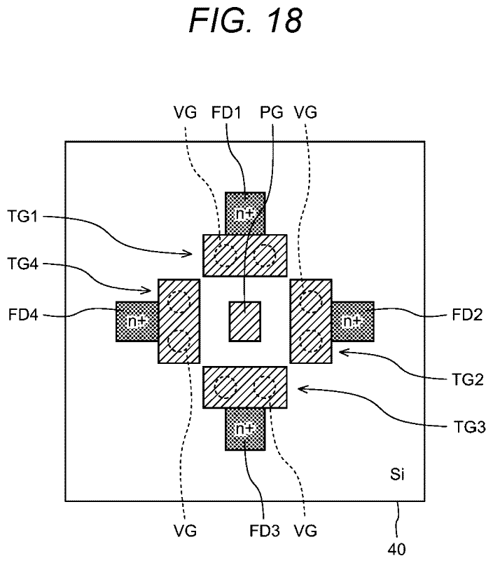

For example, as illustrated in FIG. 17, one transfer transistor TG (only the transfer transistor TG1) may be provided for one pixel, or as illustrated in FIG. 18, four transfer transistors TG1 to TG4 may be provided for one pixel, instead. Floating diffusion regions FD as charge storage units are also provided as many as the number of transfer transistors TG.

In a case where one transfer transistor TG1 is provided for one pixel, for example, the charge generated by the photodiode 41 is read in a time division manner, and a distance to an object can be obtained from a read charge distribution ratio.

In a case where four transfer transistors TG1 to TG4 are provided for one pixel, for example, a distance to an object can be obtained by a four-phase method in which charge is stored in the floating diffusion regions FD1 to FD4 while shifting a phase by 90 degrees at a time.

### 14. Number of Buried Gate Electrode Portions

In the above-described example, for example, as in the first configuration example of FIG. 2, a configuration in which one transfer transistor TG includes two buried gate electrode portions VG has been described.

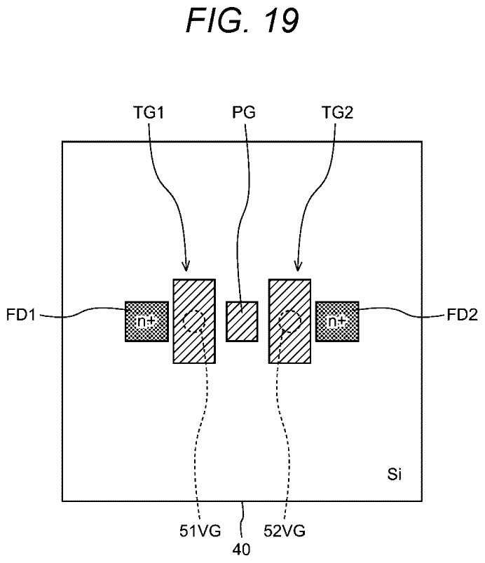

The number of the buried gate electrode portions VG included in one transfer transistor TG, however, is not limited to two, and may be another number, instead. For example, as illustrated in FIG. 19, the number of buried gate electrode portions VG included in the transfer transistor TG may be one. Alternatively, although not illustrated, the number of buried gate electrode portions VG included in the transfer transistor TG may be three or more. A planar shape of the buried gate electrode portions VG is not limited to a circular shape, and may be a polygonal shape such as a quadrangle or an octagon (including a shape whose corners are rounded).

### 15. Arrangement Example of Charge Discharge Transistor

In the first circuit configuration example illustrated in FIG. 13 and the second circuit configuration example illustrated in FIG. 14, a configuration in which the pixel 10 includes the charge discharge transistor OFG has been described.

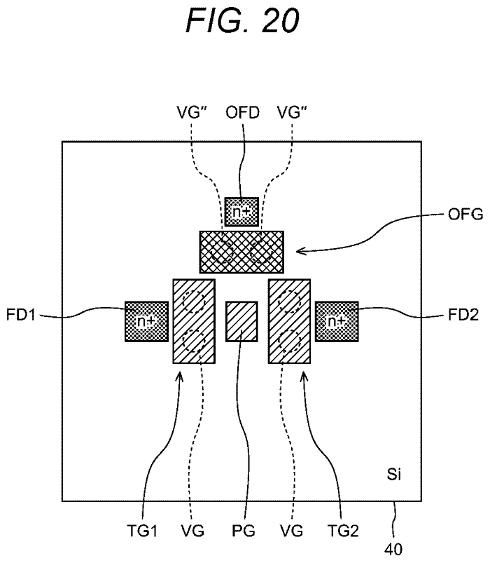

FIG. 20 is a plan view illustrating an arrangement example of the charge discharge transistor OFG.

Since the charge discharge transistor OFG is connected to the photodiode 41 and the transfer transistors TG1 and TG2 as described in the circuit configurations of FIGS. 13 and 14, the charge discharge transistor OFG is disposed in the vicinity of the photogate electrode PG as illustrated in FIG. 20. More specifically, the transfer transistors TG1 and TG2 may be arranged on two opposing sides of a quadrangle surrounding the photogate electrode PG at the center, and the charge discharge transistor OFG may be arranged on one of remaining two opposing sides of the quadrangle. The charge discharge transistor OFG may be a vertical transistor including a buried gate electrode portion VG″ similar to the buried gate electrode portion VG of the transfer transistor TG. On an outer side of the charge discharge transistor OFG, which is opposite to a photogate electrode PG side, a drain region OFD to which unnecessary charge is discharged is formed by a high-concentration n-type semiconductor region.

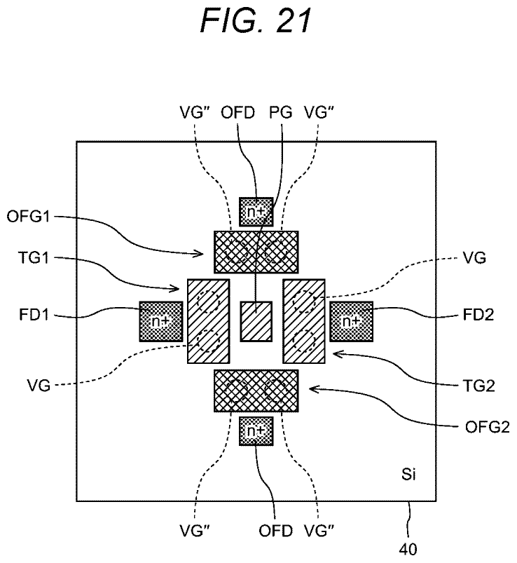

Furthermore, with respect to the charge discharge transistor OFG, two charge discharge transistors OFG1 and OFG2 that are symmetrical to each other like the two transfer transistors TG1 and TG2 may be provided as illustrated in FIG. 21. In this case, the charge discharge transistors OFG1 and OFG2 are arranged on two sides of a quadrangle surrounding the photogate electrode PG at the center different from sides on which the transfer transistors TG1 and TG2 are provided.

### 16. Arrangement Examples of Other Pixel Transistors

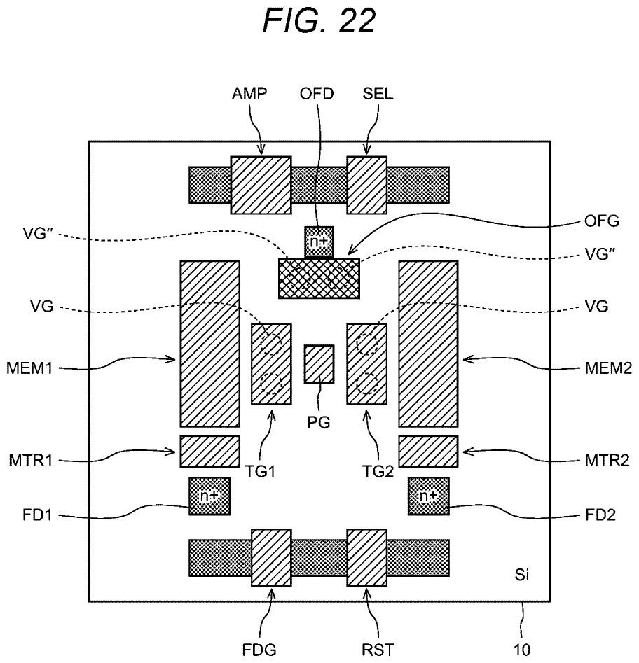

FIG. 22 is a plan view illustrating an arrangement example of the individual pixel transistors in the pixel 10 other than the first transfer transistors TG1 and TG2 in a case where the pixel is configured as indicated by the second circuit configuration example illustrated in FIG. 14.

Each pixel transistor illustrated in FIG. 22 corresponds to a pixel transistor given the same reference sign in the second circuit configuration example illustrated in FIG. 14.

The arrangement of the first transfer transistors TG1 and TG2, the memories MEM1 and MEM2, the second transfer transistors MTR1 and MTR2, and the floating diffusion regions FD1 and FD2 is similar to the first arrangement example described with reference to FIG. 15, and description thereof is omitted. Furthermore, since the arrangement of the charge discharge transistor OFG is similar to the arrangement described with reference to FIG. 20, description thereof is omitted.

The amplification transistor AMP, the selection transistor SEL, the switching transistor FDG, and the reset transistor RST are arranged in a region near a pixel boundary further outside positions where the memories MEM1 and MEM2, the memories MEM1 and MEM2, the floating diffusion regions FD1 and FD2, and the like are arranged. The amplification transistor AMP and the selection transistor SEL are arranged side by side in a region near a predetermined side (in FIG. 22, an upper side) of a quadrangular pixel region, and the switching transistor FDG and the reset transistor RST are arranged side by side in a region near another predetermined side (in FIG. 22, a lower side) of the quadrangular pixel region.

The pixel transistor arrangement illustrated in FIG. 22 is an example of a case where the amplification transistor AMP, the selection transistor SEL, the switching transistor FDG, and the reset transistor RST are included in a pixel unit, but these pixel transistors may be shared by a plurality of pixels.

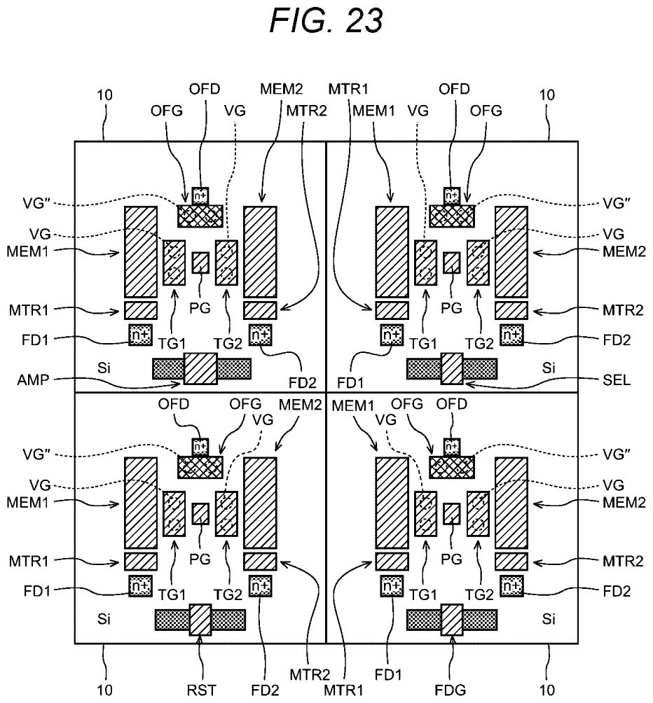

FIG. 23 is a plan view illustrating an arrangement example of the amplification transistor AMP, the selection transistor SEL, the switching transistor FDG, and the reset transistor RST in a case where the individual pixel transistors are shared by a plurality of pixels.

In the example of FIG. 23, the amplification transistor AMP, the selection transistor SEL, the switching transistor FDG, and the reset transistor RST are shared by four pixels. Any one of the amplification transistor AMP, the selection transistor SEL, the switching transistor FDG, and the reset transistor RST is arranged in each of the four pixels 10, which are a sharing unit, arranged 2×2.

Note that the sharing unit in which the pixel transistors are shared is not limited to four pixels, and the pixel transistors may be shared by a different number of pixels (for example, eight pixels), instead. Furthermore, even if the sharing unit is four pixels, for example, the pixel transistors may be shared by four pixels arranged 1×4, that is, one pixel in one of a horizontal direction and a vertical direction and four pixels in the other direction, instead of four pixels arranged 2×2.

### 17. Application Examples of Photodetection Device

The photodetection device 1 configured as described above can be used not only as a light receiving device of a distance measuring system that measures a distance to a subject by an indirect ToF method, but also as a solid-state imaging device that detects distribution of the amount of incident infrared or visible light and that captures the distribution an image.

### 18. Configuration Example of Electronic Device

The photodetection device 1 described above can be mounted, for example, on an electronic device such as a smartphone, a head mounted display, a tablet terminal, a mobile phone, a personal computer, a gaming machine, a television receiver, a wearable terminal, a digital still camera, or a digital video camera.

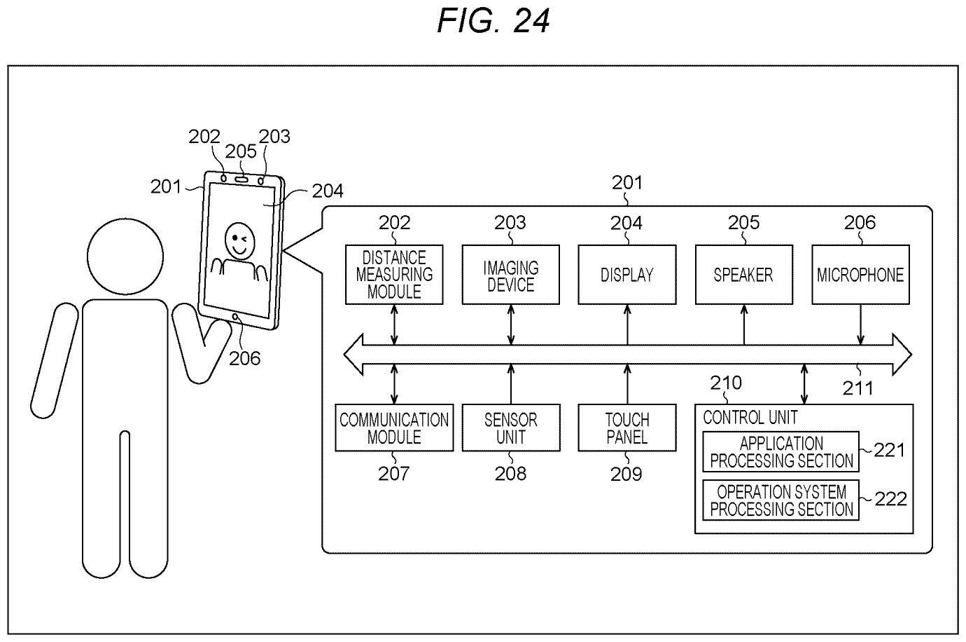

FIG. 24 is a block diagram illustrating a configuration example of a smartphone that is an electronic device on which the photodetection device 1 is mounted.

As illustrated in FIG. 24, a smartphone 201 is configured by connecting a distance measuring module 202, an imaging device 203, a display 204, a speaker 205, a microphone 206, a communication module 207, a sensor unit 208, a touch panel 209, and a control unit 210 via a bus 211. Furthermore, the control unit 210 has functions as an application processing section 221 and an operation system processing section 222 by executing a program using a CPU.

The distance measuring module 202 can include the photodetection device 1 of FIG. 1 together with a light source that emits active light. The distance measuring module 202 receives reflected light, which is light emitted from a predetermined light source and reflected from an object, and outputs a depth image in which distance information to the object is stored as a depth value. For example, the distance measuring module 202 is arranged on a front surface of the smartphone 201, measures a distance to a user of the smartphone 201, and outputs a depth value of a surface shape of the user's face, hand, finger, or the like as a distance measurement result.

The imaging device 203 is arranged on the front surface of the smartphone 201, and captures an image of the user of the smartphone 201 as a subject to obtain an image in which the user is shown. The photodetection device 1 of FIG. 1 can be applied as the imaging device 203. Note that, although not illustrated, at least one of the distance measuring module 202 and the imaging device 203 may also be arranged on a back surface of the smartphone 201.

The display 204 displays an operation screen for performing processing by the application processing section 221 and the operation system processing section 222, an image captured by the imaging device 203, and the like. The speaker 205 and the microphone 206, for example, output voice of another party and collect voice of the user at a time of making a call using the smartphone 201.

The communication module 207 performs communication over a communication network. The sensor unit 208 senses speed, acceleration, proximity, and the like, and the touch panel 209 obtains a touch operation performed by the user on the operation screen displayed on the display 204.

The application processing section 221 performs processing for providing various services on the smartphone 201. For example, the application processing section 221 may perform processing for creating a face by computer graphics virtually reproducing an expression of the user on the basis of the depth supplied from the distance measuring module 202 and displaying the same on the display 204. Furthermore, the application processing section 221 may perform processing for creating three-dimensional shape data of an arbitrary solid object, for example, on the basis of the depth supplied from the distance measuring module 202.

The operation system processing section 222 performs processing for achieving basic functions and operations of the smartphone 201. For example, the operation system processing section 222 may perform processing for authenticating the user's face and unlocking the smartphone 201 on the basis of the depth value supplied from the distance measuring module 202. Furthermore, the operation system processing section 222 may perform, for example, processing for recognizing a gesture by the user on the basis of the depth value supplied from the distance measuring module 202 and processing for inputting one of various operations according to the gesture.

In the smartphone 201 configured as described above, for example, it is possible to calculate and output distance measurement information or output a captured image of infrared light or visible light by applying the above-described photodetection device 1.

### 19. Application Example to Mobile Body

The technology of the present disclosure (present technology) can be applied to various products. For example, the technology according to the present disclosure may be implemented as a device to be mounted on any one of the following types of mobile objects: cars, electric cars, hybrid electric cars, motorcycles, bicycles, personal mobilities, airplanes, drones, ships, robots, and the like.

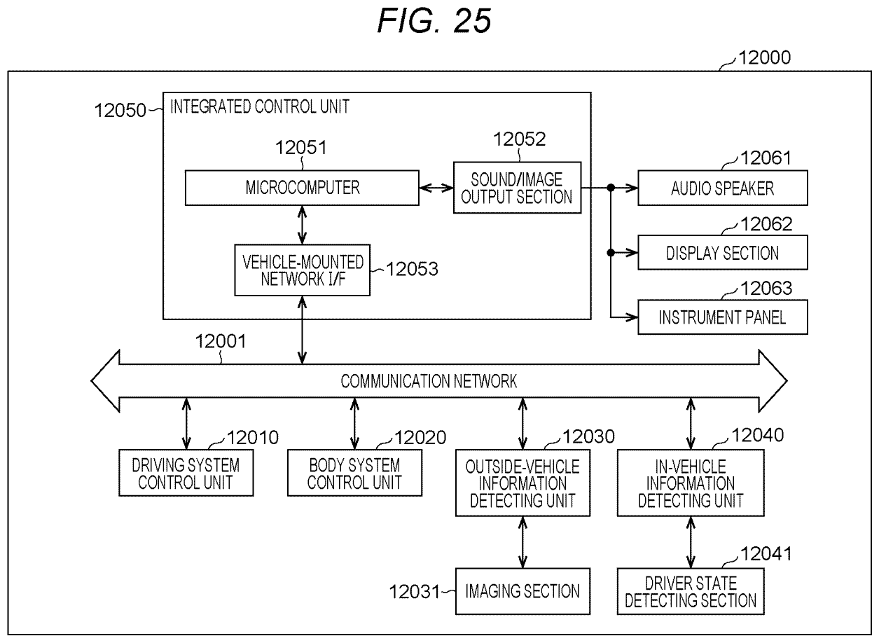

FIG. 25 is a block diagram illustrating an example of schematic configuration of a vehicle control system as an example of a mobile object control system to which the technology according to an embodiment of the present disclosure can be applied.

The vehicle control system 12000 includes a plurality of electronic control units connected to each other via a communication network 12001. In the example illustrated in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

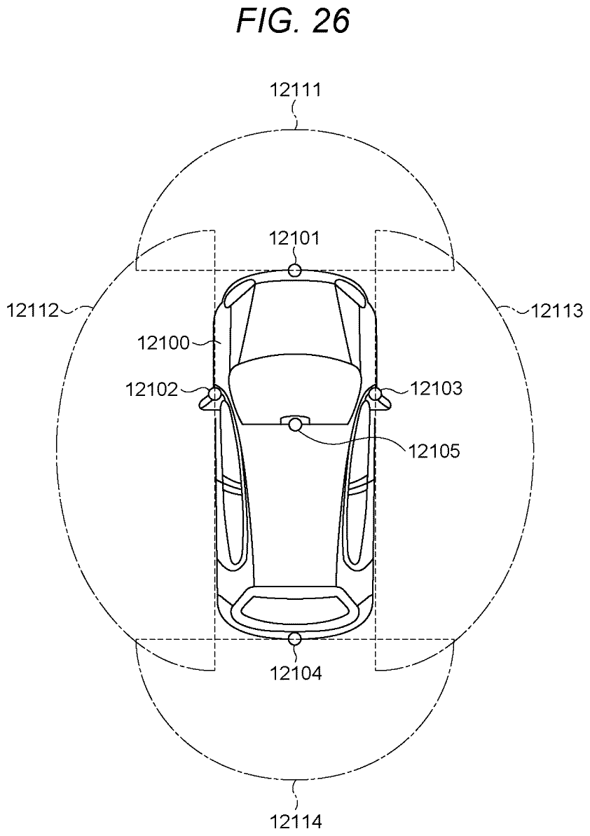

FIG. 26 is a view illustrating an example of the installation position of the imaging section 12031.

In FIG. 26, a vehicle 12100 includes imaging sections 12101, 12102, 12103, 12104, and 12105 as the imaging section 12031.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic light, a traffic sign, a lane, or the like.

Note that FIG. 26 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology of the present disclosure can be applied has been described above. The technology according to the present disclosure can be applied to the outside-vehicle information detecting unit 12030 and the in-vehicle information detecting unit 12040 among the above-described configurations. More specifically, by using distance measurement by the photodetection device 1 as the outside-vehicle information detecting unit 12030 and the in-vehicle information detecting unit 12040, it is possible to perform processing for recognizing the driver's gesture, perform one of various operations (for example, an audio system, a navigation system, and an air conditioning system) according to the gesture, and detect the state of the driver more accurately. Furthermore, it is possible to recognize unevenness of a road surface using the distance measurement performed by the photodetection device 1 or an image captured by the photodetection device 1 and reflect the recognized unevenness in the control of a suspension.

The embodiment of the present disclosure is not limited to the above-described embodiments, and various modifications may be made without departing from the gist of the technology of the present disclosure.

For example, a mode in which all or some of the plurality of configuration examples described above are combined may be employed.

Note that, the effects described in the present specification are merely examples and are not limited, and there may be effects other than those described in the present specification.

Note that the technology of the present disclosure can have the following configurations.

(1)

A photodetection device including:
a photogate electrode provided above a photodiode; and
one or more transfer transistors that transfer charge obtained as a result of photoelectric conversion performed by the photodiode to a charge storage unit, in which
the transfer transistors are vertical transistors each including a buried gate electrode portion in which a gate electrode is buried in a semiconductor substrate.
   (2)

The photodetection device according to (1), in which
in a case where an arrangement direction of the photogate electrode and the transfer transistors is defined as a first direction, width of the photogate electrode is formed in such a way as to be equal to or smaller than width of the transfer transistors in a second direction perpendicular to the first direction.
   (3)

The photodetection device according to (1) or (2), in which
the transfer transistors each include two buried gate electrode portions, and
in a case where an arrangement direction of the photogate electrode and the transfer transistors is defined as a first direction, width of the photogate electrode is formed in such a way as to be smaller than width of the two buried gate electrode portions of each transfer transistor in a second direction perpendicular to the first direction.
   (4)

The Photodetection Device According to Any One of (1) to (3), in which
the photogate electrode is a vertical gate electrode including a buried gate electrode portion buried in the semiconductor substrate.
   (5)

The photodetection device according to (4), in which
the buried gate electrode portion of the photogate electrode is formed in such a way as to be shorter than the buried gate electrode portion of each transfer transistor with respect to depth in a substrate thickness direction.
   (6)

The Photodetection Device According to Any One of (1) to (5), in which
a first voltage or a second voltage is applied to the photogate electrode.
   (7)

The photodetection device according to (6), in which the first voltage is applied to the photogate electrode during an off period, in which all of the one or more transfer transistors are turned off, and
the first voltage is a voltage higher than an off voltage for turning off the transfer transistors.
   (8)

The photodetection device according to (6) or (7), in which
the second voltage is applied to the photogate electrode during a driving period, in which two or more of the transfer transistors are alternately turned on, and
the second voltage is a voltage lower than or equal to an on voltage for turning on the transfer transistors.
   (9)

The photodetection device according to any one of (1) to (8), in which
two or four of the transfer transistors are provided for one pixel.
   (10)

The photodetection device according to any one of (1) to (9), in which
the charge storage unit includes a floating diffusion region or a MIS capacitor.
   (11)

A photodetection device including:
a photogate electrode provided above a photodiode; and
one or more transfer transistors that transfer charge obtained as a result of photoelectric conversion performed by the photodiode to a charge storage unit, in which
the photogate electrode is a vertical gate electrode including a buried gate electrode portion buried in a semiconductor substrate.
   (12)

The photodetection device according to (11), in which
the transfer transistors are vertical transistors each including a buried gate electrode portion in which a gate electrode is buried in the semiconductor substrate.
   (13)

The photodetection device according to (12), in which
in a case where an arrangement direction of the photogate electrode and the transfer transistors is defined as a first direction, width of the photogate electrode is formed in such a way as to be equal to or smaller than width of the transfer transistors in a second direction perpendicular to the first direction.
   (14)

The photodetection device according to (12) or (13), in which
the transfer transistors each include two buried gate electrode portions, and
in a case where an arrangement direction of the photogate electrode and the transfer transistors is defined as a first direction, width of the photogate electrode is formed in such a way as to be smaller than width of the two buried gate electrode portions of each transfer transistor in a second direction perpendicular to the first direction.
   (15)

The photodetection device according to any one of (12) to (14), in which
the buried gate electrode portion of the photogate electrode is formed in such a way as to be shorter than the buried gate electrode portion of each transfer transistor with respect to depth in a substrate thickness direction.
   (16)

The photodetection device according to any one of (11) to (15), in which
a first voltage or a second voltage is applied to the photogate electrode.
   (17)

The photodetection device according to (16), in which
the first voltage is applied to the photogate electrode during an off period, in which all of the one or more transfer transistors are turned off, and
the first voltage is a voltage higher than an off voltage for turning off the transfer transistors.
   (18)

The Photodetection Device According to (16) or (17), in which
the second voltage is applied to the photogate electrode during a driving period, in which two or more of the transfer transistors are alternately turned on, and
the second voltage is a voltage lower than or equal to an on voltage for turning on the transfer transistors.

### REFERENCE SIGNS LIST

1 Photodetection device
10 Pixel
40 Semiconductor substrate
41 Photodiode
51, 51′ Gate electrode
51P Planar gate electrode portion
51VG Buried gate electrode portion
52, 52′ Gate electrode
52P Planar gate electrode portion
52VG Buried gate electrode portion
61P′ Planar gate electrode portion
61VG′ Buried gate electrode portion
83 Gate electrode
93 Gate electrode
101 Gate electrode
111 Gate electrode
201 Smartphone
202 Distance measuring module
203 Imaging device
PG, PG′ Photogate electrode
TG, TG′ Transfer transistor
FD Floating diffusion region
FDG Switching transistor
FDL Additional capacitor
MEM Memory
MTR Second transfer transistor
AMP Amplification transistor
RST Reset transistor
OFG Charge discharge transistor

1. A photodetection device comprising:
a photogate electrode provided above a photodiode; and
one or more transfer transistors that transfer charge obtained as a result of photoelectric conversion performed by the photodiode to a charge storage unit, wherein
the transfer transistors are vertical transistors each including a buried gate electrode portion in which a gate electrode is buried in a semiconductor substrate.

2. The photodetection device according to claim 1, wherein
in a case where an arrangement direction of the photogate electrode and the transfer transistors is defined as a first direction, width of the photogate electrode is formed in such a way as to be equal to or smaller than width of the transfer transistors in a second direction perpendicular to the first direction.

3. The photodetection device according to claim 1, wherein
the transfer transistors each include two buried gate electrode portions, and
in a case where an arrangement direction of the photogate electrode and the transfer transistors is defined as a first direction, width of the photogate electrode is formed in such a way as to be smaller than width of the two buried gate electrode portions of each transfer transistor in a second direction perpendicular to the first direction.

4. The photodetection device according to claim 1, wherein
the photogate electrode is a vertical gate electrode including a buried gate electrode portion buried in the semiconductor substrate.

5. The photodetection device according to claim 4, wherein
the buried gate electrode portion of the photogate electrode is formed in such a way as to be shorter than the buried gate electrode portion of each transfer transistor with respect to depth in a substrate thickness direction.

6. The photodetection device according to claim 1, wherein
a first voltage or a second voltage is applied to the photogate electrode.

7. The photodetection device according to claim 6, wherein
the first voltage is applied to the photogate electrode during an off period, in which all of the one or more transfer transistors are turned off, and
the first voltage is a voltage higher than an off voltage for turning off the transfer transistors.

8. The photodetection device according to claim 6, wherein
the second voltage is applied to the photogate electrode during a driving period, in which two or more of the transfer transistors are alternately turned on, and
the second voltage is a voltage lower than or equal to an on voltage for turning on the transfer transistors.

9. The photodetection device according to claim 1, wherein
two or four of the transfer transistors are provided for one pixel.

10. The photodetection device according to claim 1, wherein
the charge storage unit includes a floating diffusion region or a MIS capacitor.

11. A photodetection device comprising:
a photogate electrode provided above a photodiode; and
one or more transfer transistors that transfer charge obtained as a result of photoelectric conversion performed by the photodiode to a charge storage unit, wherein
the photogate electrode is a vertical gate electrode including a buried gate electrode portion buried in a semiconductor substrate.

12. The photodetection device according to claim 11, wherein
the transfer transistors are vertical transistors each including a buried gate electrode portion in which a gate electrode is buried in the semiconductor substrate.

13. The photodetection device according to claim 12, wherein
in a case where an arrangement direction of the photogate electrode and the transfer transistors is defined as a first direction, width of the photogate electrode is formed in such a way as to be equal to or smaller than width of the transfer transistors in a second direction perpendicular to the first direction.

14. The photodetection device according to claim 12, wherein
the transfer transistors each include two buried gate electrode portions, and
in a case where an arrangement direction of the photogate electrode and the transfer transistors is defined as a first direction, width of the photogate electrode is formed in such a way as to be smaller than width of the two buried gate electrode portions of each transfer transistor in a second direction perpendicular to the first direction.

15. The photodetection device according to claim 12, wherein
the buried gate electrode portion of the photogate electrode is formed in such a way as to be shorter than the buried gate electrode portion of each transfer transistor with respect to depth in a substrate thickness direction.

16. The photodetection device according to claim 11, wherein
a first voltage or a second voltage is applied to the photogate electrode.

17. The photodetection device according to claim 16, wherein
the first voltage is applied to the photogate electrode during an off period, in which all of the one or more transfer transistors are turned off, and
the first voltage is a voltage higher than an off voltage for turning off the transfer transistors.

18. The photodetection device according to claim 16, wherein
the second voltage is applied to the photogate electrode during a driving period, in which two or more of the transfer transistors are alternately turned on, and
the second voltage is a voltage lower than or equal to an on voltage for turning on the transfer transistors.
